(19) United States
(12) Patent Application Publication
(10) Pub. No.: US 2026/0173628 A1
(43) Pub. Date: Jun. 18, 2026

(54) MICRO-LED DISPLAY CO-PACKAGED WITH OPTICS AND METHOD OF FABRICATION

(71) Applicant: Hyperlume Inc., Toronto (CA)

(72) Inventors: MOHSEN ASAD, OTTAWA (CA); HOSSEIN FARIBORZI, AUBURNDALE, MA (US)

(21) Appl. No.: 18/711,591

(22) PCT Filed: Nov. 18, 2022
(86) PCT No.: PCT/IB2022/061160

§ 371 Date: Jul. 3, 2025

Related U.S. Application Data
(60) Provisional application No. 63/280,620, filed on Nov. 18, 2021.

(51) Int. Cl. H10H 29/855; G02B 27/01; G02F 1/13357; H10H 29/01; H10H 29/32; H10H 29/851

(52) U.S. Cl. CPC H10H 29/855; G02B 27/0172; G02F 1/133603; H10H 29/011; H10H 29/012; H10H 29/0361; H10H 29/0363; H10H 29/0364; H10H 29/32; H10H 29/8515; H10H 29/8552

(57) ABSTRACT

A display including light emitting diodes (LEDs) fabricated on an LED wafer, light reflecting sidewalls coating side surfaces of each of the LEDs, and LED bonding pads fabricated on the LED wafer. The LED bonding pads being electrically connected to the LEDs. The display also including a color conversion optical wafer bonded to the LED wafer to covert light emitted from the LEDs, a light manipulating optical wafer bonded to the color conversion optical wafer to manipulate the converted light emitted from the color conversion optical wafer, and LED driver circuits including driver circuit bonding pads bonded to the LED bonding pads to electrically connect the LED driver circuits to the LEDs.

### FIELD

Method of fabrication of a micro-LED display co-packaged with optics.

### BACKGROUND

Micro-LEDs are normally constructed from gallium-nitride (GaN) or gallium arsenide (GaAs) based materials, and are constructed to have light emission angles maximized between 40 to 140 degrees. If the light emitted from the micro-LEDs is to be coupled to an external waveguide (e.g. for fiber-optic transmission, or optical pupil and combiner), additional optics such as a geometric lens may be required to couple the light into the waveguide. However, conventional optics and their method of assembly are not suitable for applications within small spaces and small footprints.

In addition, micro-LED efficiency degrades during scaling down the size using a conventional top-down fabrication process. Specifically, dangling bonds and defects generated during the etching process reduce the effective recombination efficiency and the final efficiency of the micro-LED. This efficiency degradation is also worsened when the surface-to-volume ratio of the micro-LEDs is larger.

### SUMMARY

A display comprising light emitting diodes (LEDs) fabricated on an LED wafer, light reflecting sidewalls coating side surfaces of each of the LEDs, and LED bonding pads fabricated on the LED wafer. The LED bonding pads being electrically connected to the LEDs. The display also comprising a color conversion optical wafer bonded to the LED wafer to covert light emitted from the LEDs, a light manipulating optical wafer bonded to the color conversion optical wafer to manipulate the converted light emitted from the color conversion optical wafer, and LED driver circuits including driver circuit bonding pads bonded to the LED bonding pads to electrically connect the LED driver circuits to the LEDs.

A method of manufacturing a display. The method comprising fabricating light emitting diodes (LEDs) on an LED wafer, fabricating light reflecting sidewalls coating side surfaces of each of the LEDs, fabricating LED bonding pads on the LED wafer, the LED bonding pads being electrically connected to the LEDs, fabricating a color conversion optical wafer bonded to the LED wafer to covert light emitted from the LEDs, fabricating a light manipulating optical wafer bonded to the color conversion optical wafer to manipulate the converted light emitted from the color conversion optical wafer, temporarily connecting the LED bonding pads to a test circuit and confirming operation of the LEDs, removing the LED bonding pads from the test circuit when operation of the LEDs are confirmed, and aligning and electrically connecting the LED bonding pads to driver bonding pads of LED driver circuits to electrically connect the LED driver circuits to the LEDs.

A display comprising light emitting diodes (LEDs) fabricated on an LED wafer, light reflecting sidewalls coating side surfaces of each of the LEDs, and LED bonding pads fabricated on the LED wafer. The LED bonding pads being electrically connected to the LEDs. The display also comprising a color conversion optical wafer bonded to the LED wafer to covert light emitted from the LEDs, and a light manipulating optical wafer bonded to the color conversion optical wafer to manipulate the converted light emitted from the color conversion optical wafer.

A method of manufacturing a display. The method comprising fabricating light emitting diodes (LEDs) on an LED wafer, fabricating light reflecting sidewalls coating side surfaces of each of the LEDs; fabricating LED bonding pads on the LED wafer, the LED bonding pads being electrically connected to the LEDs, fabricating a color conversion optical wafer bonded to the LED wafer to covert light emitted from the LEDs, and fabricating a light manipulating optical wafer bonded to the color conversion optical wafer to manipulate the converted light emitted from the color conversion optical wafer.

### BRIEF DESCRIPTION OF THE DRAWINGS

So that the manner in which the above recited features of the present disclosure can be understood in detail, a more particular description of the disclosure, briefly summarized above, may be had by reference to example embodiments, some of which are illustrated in the appended drawings. It is to be noted, however, that the appended drawings illustrate only example embodiments of this disclosure and are therefore not to be considered limiting of its scope, for the disclosure may admit to other equally effective example embodiments.

FIG. 1 is a flowchart describing the fabrication of a micro-LED display, according to an example embodiment of the disclosure.

FIG. 2 illustrates the micro-device substrate after epitaxial layer growth thereon, according to an example embodiment of the disclosure.

FIG. 3A illustrates the micro-LED pixels on the micro-device substrate, according to an example embodiment of the disclosure.

FIG. 3B illustrates the micro-LED pixels on the micro-device substrate with a thin epitaxial layer remaining on the micro-device substrate between the micro-LED pixels, according to an example embodiment of the disclosure.

FIG. 4 illustrates the micro-LED pixels with sidewall passivation layers, according to an example embodiment of the disclosure.

FIG. 5 illustrates the micro-LED arrays after surface planarization, according to an example embodiment of the disclosure.

FIG. 6 illustrates the micro-LED arrays after opening vias in the planarization film, according to an example embodiment of the disclosure.

FIG. 7 illustrates a micro-LED structure where the vias are filled with a conductive material such as metal, according to an example embodiment of the disclosure.

FIG. 8 illustrates a micro-LED array after growing or depositing a transparent conductive layer thereon, according to an example embodiment of the disclosure.

FIG. 9A illustrates a micro-LED array with overgrown epitaxial layer after pixel formation and sidewall passivation, according to an example embodiment of the disclosure.

FIG. 9B illustrates a conductive transparent contact on the overgrown epitaxial layer, according to an example embodiment of the disclosure.

FIG. 10 illustrates an optically transparent substrate, according to an example embodiment of the disclosure.

FIG. 11 illustrates the optical substrate with optical elements created thereon, according to an example embodiment of the disclosure.

FIG. 12 illustrates the optical substrate with optical elements covered (coated) with an additional layer, according to an example embodiment of the disclosure.

FIG. 13 illustrates the optical substrate with black matrices thereon, according to an example embodiment of the disclosure.

FIG. 14 illustrates the optical substrate covered with a reflective layer, according to an example embodiment of the disclosure.

FIG. 15 illustrates directional (anisotropic) removal (etching) of portions of the reflective layer, according to an example embodiment of the disclosure.

FIG. 16 illustrates the optical substrate with reflective layers coated on the black matrices' sidewalls, according to an example embodiment of the disclosure.

FIG. 17 illustrates the optical substrate where the space between black matrices is filled with color conversion materials, according to an example embodiment of the disclosure.

FIG. 18 illustrates the alignment process of the micro-LEDs with the optical substrate with optical elements thereon, according to an example embodiment of the disclosure.

FIG. 19 illustrates the alignment process of the micro-LEDs (on micro-device substrate) with the optical substrate with optical elements thereon, according to an example embodiment of the disclosure.

FIG. 20 illustrates micro-LED structure after integration with the optical substrate, according to an example embodiment of the disclosure.

FIG. 21 illustrates the micro-device substrate removal, according to an example embodiment of the disclosure.

FIG. 22 illustrates the micro-LEDs after backside electrode processing, according to an example embodiment of the disclosure.

FIG. 23 illustrates the micro-LED array where the backside electrode is fabricated with sharp tips, according to an example embodiment of the disclosure.

FIG. 24 illustrates the micro-LED structure with backside electrode (bonding pads) where the space between back electrodes is filled with a dielectric, according to an example embodiment of the disclosure.

FIG. 25 illustrates the alignment process of micro-LED structure (integrated with optical substrate) with the driving circuit, according to an example embodiment of the disclosure.

FIG. 26 illustrates the micro-LED arrays after integration with driving circuits, according to an example embodiment of the disclosure.

FIG. 27 illustrates path of an arbitrary photon (light path) emitted from the micro-LEDs, according to an example embodiment of the disclosure.

FIG. 28 illustrates a micro-LED display with another type of optical elements that are concave or convex in shape, according to an example embodiment of the disclosure.

FIG. 29 illustrates a micro-LED display with optical elements fabricated on (or in) both sides of the optical substrate, according to an example embodiment of the disclosure.

FIG. 30A illustrates a micro-LED display with optical elements (flat-optics, or conventional lenses) on the topside of the optical substrate, according to an example embodiment of the disclosure.

FIG. 30B illustrates a micro-LED display with optical elements (Recessed Optics or Diffractive Optical Element) on the topside of the optical substrate, according to an example embodiment of the disclosure.

FIG. 31 illustrates a micro-LED display integrated with a polarizer and multi-layer liquid crystal active optical element, according to an example embodiment of the disclosure.

FIG. 32 illustrates a micro-LED display integrated with a polarizer and liquid crystal optical element that may be tuned with an electrical voltage, according to an example embodiment of the disclosure.

FIG. 33 illustrates a system assembly structure where a micro-LED display integrated with an active optical element are assembled on an organic substrate with electrical contacts, according to an example embodiment of the disclosure.

FIG. 34 is a flowchart describing the fabrication of a micro-LED display, according to an example embodiment of the disclosure.

FIG. 35A illustrates a silicon substrate with crystal orientation [100], according to an example embodiment of the disclosure.

FIG. 35B illustrates a silicon-on-insulator substrate with crystal orientation [100], according to an example embodiment of the disclosure.

FIG. 36 illustrates a silicon substrate with a patterned dielectric layer, according to an example embodiment of the disclosure.

FIG. 37A illustrates the cross-section and top view of the substrate after directional etching to expose planes, according to an example embodiment of the disclosure.

FIG. 37B illustrates the cross-section of a silicon substrate after directional etching followed by coating and patterning a dielectric layer, according to an example embodiment of the disclosure.

FIG. 38A illustrates the epitaxial layers grown on the patterned silicon substrate to create micro-LEDs, according to an example embodiment of the disclosure.

FIG. 38B illustrates the epitaxial layers grown on the patterned silicon substrate to create micro-LEDs, according to an example embodiment of the disclosure.

FIG. 38C illustrates the epitaxial layers overgrown on the patterned silicon substrate to create micro-LEDs, according to an example embodiment of the disclosure.

FIG. 39A illustrates the silicon substrate with epitaxial layers after removing the dielectric layer, according to an example embodiment of the disclosure.

FIG. 39B illustrates the silicon substrate with epitaxial layers after removing the dielectric layer, according to an example embodiment of the disclosure.

FIG. 40A illustrates a common top electrode on the epitaxial layer, according to an example embodiment of the disclosure.

FIG. 40B illustrates a common top electrode on the epitaxial layer, according to an example embodiment of the disclosure.

FIG. 40C illustrates a common top electrode on the overgrown epitaxial layer, according to an example embodiment of the disclosure.

FIG. 41A illustrates the epitaxial micro-LEDs integrated with an optical substrate with optical elements and color conversion layers, according to an example embodiment of the disclosure.

FIG. 41B illustrates the overgrown epitaxial micro-LEDs integrated with an optical substrate with optical elements and color conversion layers, according to an example embodiment of the disclosure.

FIG. 42A illustrates the substrate release process to remove the silicon substrate and expose the micro-LEDs' backside, according to an example embodiment of the disclosure.

FIG. 42B illustrates the substrate release process to remove the silicon substrate and expose the micro-LEDs' backside, according to an example embodiment of the disclosure.

FIG. 43A illustrates the micro-LEDs' backside after a dielectric layer coating, patterning and back-contact metal coating, according to an example embodiment of the disclosure.

FIG. 43B illustrates the micro-LEDs' backside after back-contact metal coating and patterning, according to an example embodiment of the disclosure.

FIG. 44A illustrates the alignment of the micro-LEDs with the driving circuit substrate, according to an example embodiment of the disclosure.

FIG. 44B illustrates the alignment of the micro-LEDs with the driving circuit substrate, according to an example embodiment of the disclosure.

FIG. 45A illustrates the micro-LED display after bonding micro-LEDs to driving circuit pads, according to an example embodiment of the disclosure.

FIG. 45B illustrates the micro-LED display after bonding micro-LEDs to driving circuit pads, according to an example embodiment of the disclosure.

FIG. 46 illustrates the alignment between micro-LEDs and CMOS substrate where the space between micro-LEDs is filled with a dielectric or polymer.

FIG. 47A illustrates the micro-LED display after integration of the micro-LEDs and driving circuit, with the optical path of a photon shown, according to an example embodiment of the disclosure.

FIG. 47B illustrates the hybrid bonding micro-LED and driving circuit, with the optical path of a photon shown, according to an example embodiment of the disclosure.

FIG. 48 illustrates the silicon substrate patterned by selective chemical etching, according to an example embodiment of the disclosure.

FIG. 49 illustrates the epitaxial layer grown on the patterned silicon substrate where the active region is grown higher than the silicon wafer pattern depth, according to an example embodiment of the disclosure.

FIG. 50 illustrates the epitaxial layers may have different phase or crystal orientation inside the patterned silicon region, according to an example embodiment of the disclosure.

FIG. 51 illustrates a transparent contact on the micro-LED pixels, according to an example embodiment of the disclosure.

FIG. 52 illustrates the structure with an overgrown epitaxial layer, according to an example embodiment of the disclosure.

FIG. 53 illustrates a transparent contact created over the overgrown epitaxial layer, according to an example embodiment of the disclosure.

FIG. 54 illustrates the micro-LED structures integrated with an optical substrate, according to an example embodiment of the disclosure.

FIG. 55 illustrates the silicon substrate removal process, according to an example embodiment of the disclosure.

FIG. 56 illustrates the micro-LED structure alignment with a driving circuit substrate, according to an example embodiment of the disclosure.

FIG. 57 illustrates the alignment of a micro-LED structure and driving circuit pads where the space between the micro-LEDs and circuit pads is filled with a dielectric material or polymer, according to an example embodiment of the disclosure.

FIG. 58 illustrates the alignment process of micro-LED structure and backplane where the micro-LED pads are covered with an adhesive polymer, according to an example embodiment of the disclosure.

FIG. 59 illustrates the micro-LED structure bonded to the driving circuit, according to an example embodiment of the disclosure.

FIG. 60A illustrates a micro-LED display co-packaged with optics, according to an example embodiment of the disclosure.

FIG. 60B illustrates a micro-LED display co-packaged with recessed optical elements or diffractive optical elements, according to an example embodiment of the disclosure.

FIG. 61 illustrates a micro-LED display where a cathode electrode is covering the sidewalls, where micro-LED epitaxial layer is fabricated from different crystal phases, according to an example embodiment of the disclosure.

FIG. 62 illustrates a micro-LED emitter co-packaged with optics to couple the photons into the waveguides, according to an example embodiment of the disclosure.

FIG. 63 illustrates a micro-LED array co-packaged with optics to guide the photons and enhance the light coupling into the waveguide, according to an example embodiment of the disclosure.

FIG. 64 illustrates lateral (flip-chip) micro-LEDs co-packaged with optics to couple the photons into waveguides, according to an example embodiment of the disclosure.

FIG. 65 is a flowchart describing the fabrication of a micro-LED display and Integration with driving micro-ICs, according to an example embodiment of the disclosure.

FIG. 66A illustrates a carrier substrate with an adhesive layer thereon, according to an example embodiment of the disclosure.

FIG. 66B illustrates a carrier substrate with an adhesive layer and a sacrificial layer thereon, according to an example embodiment of the disclosure.

FIG. 67 illustrates a pick-and-place process to transfer a micro-IC to a carrier substrate, according to an example embodiment of the disclosure.

FIG. 68 illustrates micro-ICs transferred onto a carrier substrate with a desired arrangement, according to an example embodiment of the disclosure.

FIG. 69 illustrates micro-ICs transferred onto a carrier substrate with a desired arrangement, according to an example embodiment of the disclosure.

FIG. 70 illustrates embedding micro-ICs in a molding material, according to an example embodiment of the disclosure.

FIG. 71 illustrates assembling a secondary substrate to the molding material, according to an example embodiment of the disclosure.

FIG. 72 illustrate the carrier substrate removal process, according to an example embodiment of the disclosure.

FIG. 73 illustrates the micro-ICs embedded in molding material after substrate removal, according to an example embodiment of the disclosure.

FIG. 74 illustrates the adhesive layer removal to expose the micro-IC's pads, according to an example embodiment of the disclosure.

FIG. 75 illustrates the micro-ICs embedded in molding material with exposed electrical pads, according to an example embodiment of the disclosure.

FIG. 76 illustrates the micro-IC substrate after forming redistribution layers, electrical pads and vias, according to an example embodiment of the disclosure.

FIG. 77 illustrates a micro-LED integrated onto a micro-IC substrate, according to an example embodiment of the disclosure.

FIG. 78 illustrates a micro-LED display co-packaged with optics, according to an example embodiment of the disclosure.

FIG. 79 illustrates a micro-LED display co-packaged with optics, according to an example embodiment of the disclosure.

FIG. 80 illustrate a test process to qualify the micro-LED functionality before assembly to micro-ICs, according to an example embodiment of the disclosure.

### DETAILED DESCRIPTION OF THE DRAWING

Various example embodiments of the present disclosure will now be described in detail with reference to the drawings. It should be noted that the relative arrangement of the components and steps, the numerical expressions, and the numerical values set forth in these example embodiments do not limit the scope of the present disclosure unless it is specifically stated otherwise. The following description of at least one example embodiment is merely illustrative in nature and is in no way intended to limit the disclosure, its application, or its uses. Techniques, methods and apparatus as known by one of ordinary skill in the relevant art may not be discussed in detail but are intended to be part of the specification where appropriate. In all the examples illustrated and discussed herein, any specific values should be interpreted to be illustrative and non-limiting. Thus, other example embodiments could have different values. Notice that similar reference numerals and letters refer to similar items in the following figures, and thus once an item is defined in one figure, it is possible that it need not be further discussed for the following figures. Below, the example embodiments will be described with reference to the accompanying figures.

In order to reduce cost of a display, smaller and smaller micro-LEDs are desired to be fabricated and integrated while simultaneously maintaining device efficiency. As a result, it is beneficial to reduce the non-radiative recombination at defective LED sidewalls, or by growing micro-LEDs in a way which does not require further etching processing. By controlling the plane of the epitaxial layer to non-polar plane, higher optical modulation bandwidth and quantum efficiency are also feasible. Also, surface flatness (e.g. in the range of less than 3 nm) and cleanliness of the interface are beneficial in packaging high resolution micro-LED patterns on a CMOS driving backplanes. Furthermore, thermal curing for improving the bond quality may degrade the optical properties of the display. As a result, it is beneficial for the epitaxial growth process to be modified in a way to not only optimizes the device efficiency, but also provides 3D structures that are useful for packaging into display devices and optical transmitter devices among others.

The disclosure described herein provides solutions for growing an epitaxial layer selectively in a patterned silicon substrate in order to achieve 3D micro-LED structures with reliable integration capabilities, and also to maintain the device efficiency while shrinking the size of the structures. The proposed epitaxial growth structure benefits from non-polar crystal structures and is able to be modulated at higher frequencies. In addition, techniques and methods are provided to integrate the passive and active optical elements into the display in a wafer-level that is compatible with the remainder of the fabrication process. The proposed solution has many applications and may be used for augmented/virtual reality (AR/VR) displays, optical communications (e.g. fiber optics), artificial intelligence (AI), and machine learning (ML) applications among others.

Generally, the methods/structures are for integrating optical elements onto a micro-LED display to guide the light, manipulate the direction of the light, improve the light extraction and the light coupling into a further waveguide for use in applications such as AR/VR displays (e.g. goggles/headset), optical communications, 5G networks, AI and ML applications and data centers. The structure includes a fan-out wafer-level-bonding to arrange and integrate micro-ICs on a carrier substrate and the methods to applying molding material, create redistribution layers, through substrate vias and an overall micro-LED assembly. For example, the methods may grow an epitaxial layer in groove-shaped silicon structure to provide a self-aligned patterned micro-LED structure with sharp back-electrodes, a method to release the micro-LED from the substrate, and integrate the released micro-LED onto driving circuits, and a method to create polar and non-polar crystal structures on silicon substrates. The methods include co-packaging optics into micro-LED displays for guiding and manipulation the light. The resultant structure extracts the photons from micro-LED and displays and couples them efficiently with low insertion-loss. The method also includes co-packaging optics onto the liquid crystal display to change the focal length, manipulate the emission direction, and enhance the contrast and pixel density.

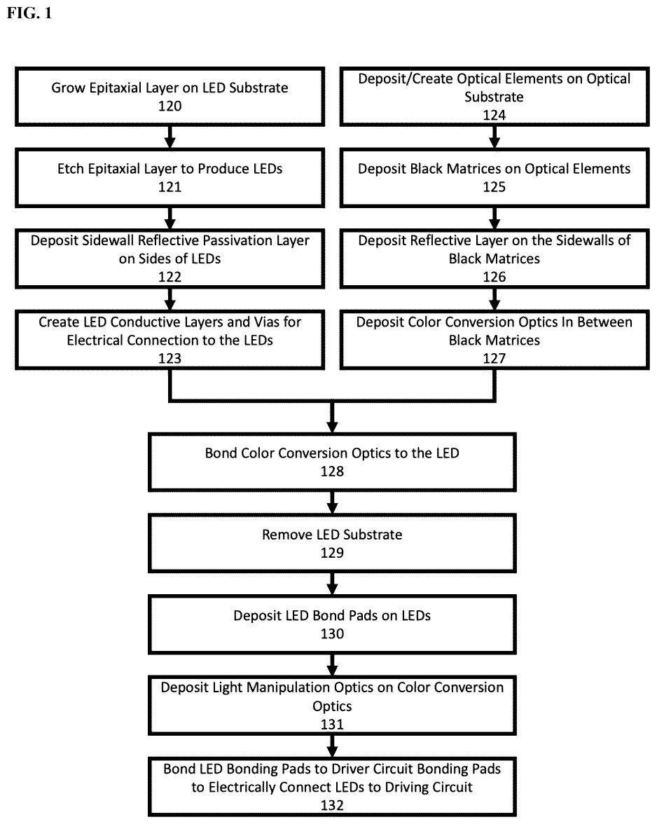

FIG. 1 illustrates an example fabrication process of a micro-LED display with rectangular shaped LEDs. Generally, the LEDs and optics are fabricated separately and then bonded together to form the micro-LED display. It is noted that additional steps not shown in FIG. 1 may also be executed when fabricating the micro-LED display.

Steps 120-123 describe the fabrication of the LEDs on the substrate. Specifically, in step 120, an epitaxial layer is grown on an LED substrate (e.g. silicon substrate), and in step 121, the epitaxial layer is etched to produce LEDs having a particular shape (e.g. rectangular shape), although other shapes (e.g. round, etc.) are possible depending on the etching pattern. Then, in step 122, reflective sidewalls are deposited on the sides of the LEDs, and in step 123, conductive layers (e.g. RDLs) and other electrical connections (e.g. bonding pads, etc.) are formed to provide electrical connections to/from the LEDs.

Steps 124-127 describe the fabrication of the optics. Specifically, in step 124, the optical elements (e.g. lenses for light collection, etc.) are deposited on the optics substrate, and in step 125, optical blockers such as black matrices are deposited on the optical elements to block regions of the optics from receiving light. Then, in step 126, reflective material is deposited on portions of the black matrices, and in step 127, color conversion optics are deposited in between the black matrices.

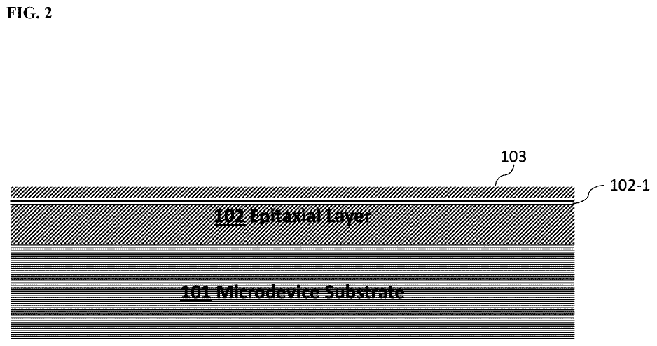

Steps 128-132 describe the bonding of the LEDs with the optics. Specifically, in step 128, the color conversion optics are bonded to the LEDs, and in step 129, the LED substrate is removed. Then, in step 130, bonding pads are deposited on the LEDs, and in step 131, additional light manipulating optics (e.g. lenses for light homogenization, collimation, focal point manipulation, etc.) are deposited on the color conversion optics. Furthermore, in step 132, the LED bonding pads are bonded to driver circuit bonding pads to electrically connect the LEDs to the driver circuits. The steps described in FIG. 1 will now be described in further detail with respect to FIGS. 2-33 below.

FIG. 2 illustrates an epitaxial layer 102 grown on a micro-device substrate 101. The growth process may be performed using metal-organic chemical vapor deposition (MOCVD) or molecular beam epitaxy (MBE) processes. The active region contains quantum wells (QWs) 102-1. The top layer 103 may be a highly doped p-type semiconductor, where the top layer 103 doping may be activated after epitaxial growth.

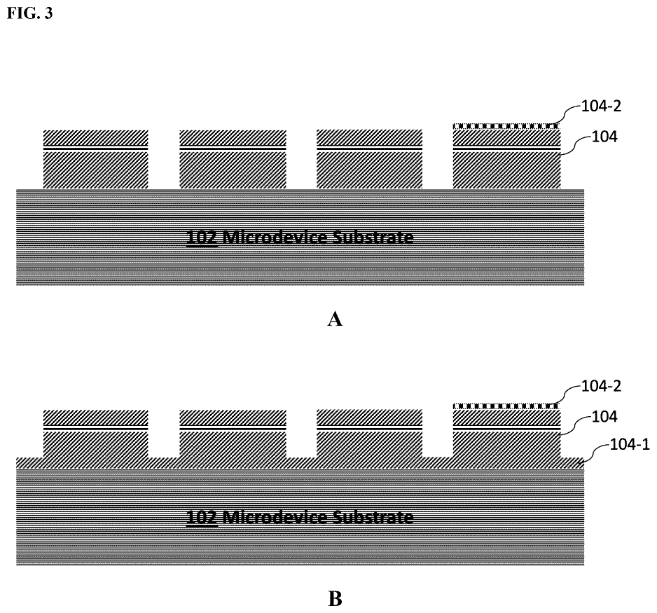

FIGS. 3A and 3B illustrate micro-LED pixels 104 after patterning the epitaxial layer. The whole epitaxy layer may be etched to expose the substrate as shown in FIG. 2A, or a thin layer 104-1 of the epitaxial layer may be kept on the growth substrate as shown in FIG. 2B. This thin layer may be used as an etch-stop during the substrate removal process or backside thinning. As shown in the rightmost pixel, a thin conductive layer 104-2 for creating an ohmic contact on the surface may be coated in this step or may be created in a later process. The epitaxial layer pixelation process may contain steps such as dielectric coating, lithography, dry or wet etching, and defect removal.

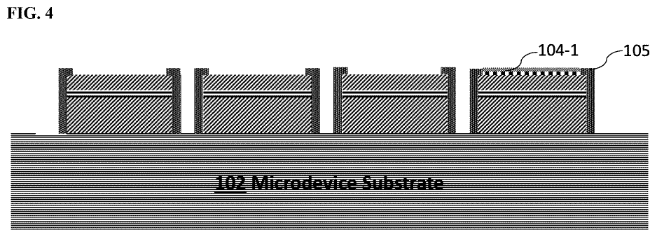

It is noted that light is emitted from the micro-LED pixel active region 102-1 in all directions and therefore some light may be lost into adjacent pixels and into the substrate. In order to harvest as many of the emitted photons as possible, a reflective layer between the pixels may be employed. For example, FIG. 4 illustrates the micro-LED pixels after a reflective sidewall passivation layer 105 coating is deposited on the micro-LED pixels to reflect light emitted from the LEDs towards an emission opening on the top of the LED. Passivation layer 105 may be created using atomic layer deposition (ALD), plasma-enhanced chemical vapor deposition (PECVD), or a combination of chemical and physical treatment. Processes such as surface coating, lithography and etching may be used to pattern the passivation layer 105 and expose the pixel topside or top contact 104-2.

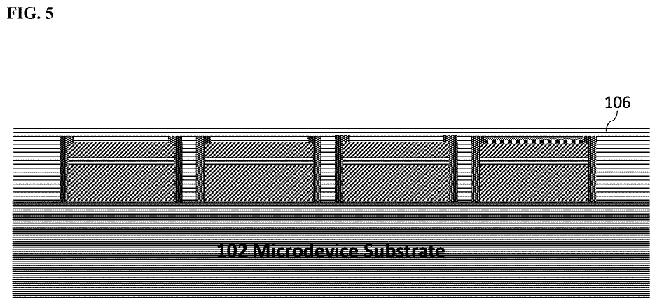

FIG. 5 illustrates surface planarization of the micro-LEDs using a polymer or dielectric 106. The polymer may be spin-coated or blade coated on the substrate to control the thickness and surface profile. Additional ultraviolet or thermal curing may be implemented to change the adhesion or mechanical properties of the planarization material 106. The curing process increases the hardness of the planarization material 106.

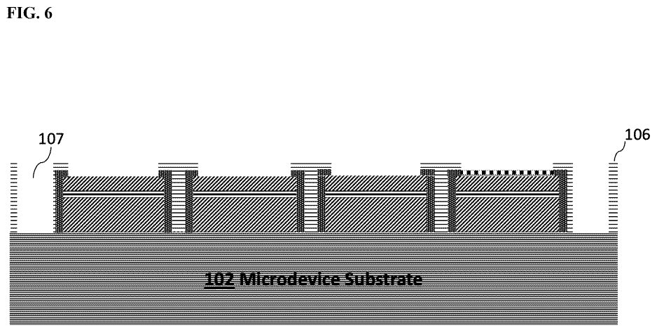

FIG. 6 illustrates vias 107 creating process in the planarization material 106. A lithography process followed by etching (physical or chemical) may be used to pattern the planarized layer. After patterning, the micro-LED topside may be accessible through the via 107. Also, the through polymer via 107 is ready for further processing such as filling with conductive materials. The planarization material 106 may fill the gap between the micro-LEDs and keep them ordered during the subsequent transfer process.

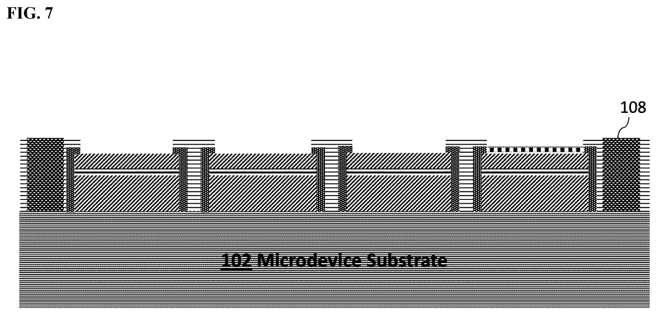

FIG. 7 illustrates the structure after completion of the through polymer via process, where the via 107 is filled with a conductive metal (108) such as gold or copper Processes such as electroplating, coating may be used to fill the via with a metal. Other processing such as lithography and etching may also be used in this step.

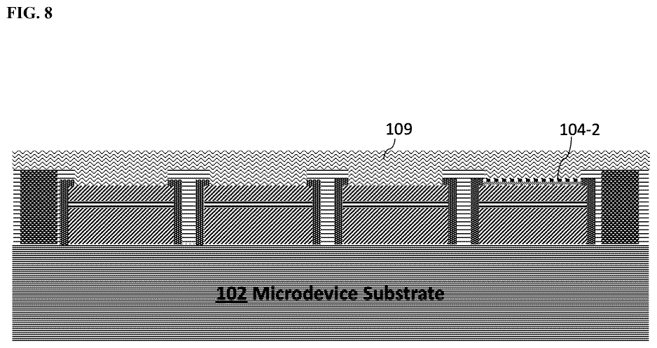

A conductive layer 109 is then coated on the micro-LEDs as shown in the FIG. 8. This conductive layer 109 may be made from conductive transparent oxide such as indium titanium oxide (ITO) or aluminum doped zinc oxide (AZO) to allow photon transmission. The conductive layer connects the micro-LED anode electrodes 104-2 to the conductive metal 108 of the vias 107. If the ohmic contact layer on the micro-LEDs has not been created in the early steps, this common electrode may also be used as an ohmic contact directly to micro-LEDs (e.g. 109 may connect directly to the LEDs without the use of 104-2). Other processes such as rapid thermal annealing may also be implemented.

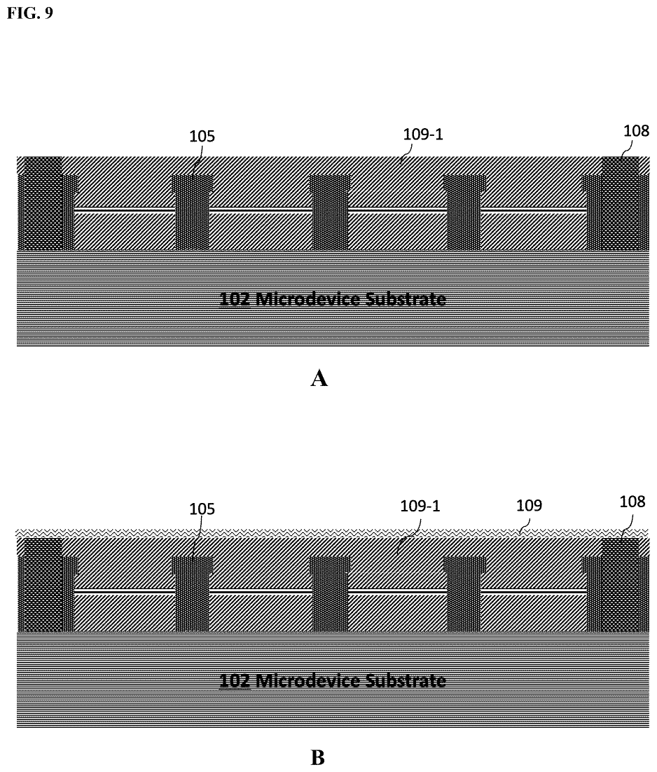

FIG. 9A illustrates an example of micro-LEDs with an overgrown epitaxial layer 109-1 after the pixilation process and the addition of the sidewall passivation layers. In this example, the overgrowth layer 109-1 electrically connects the micro-LEDs top surfaces to each other to create a common electrode on the topside of the LEDs. The via 108 may be formed after overgrowth step by patterning the surface using lithography and etching processes.

As shown in FIG. 9B, the conductive transparent layer 109 may be created on the overgrown epitaxial layer as an ohmic contact and current spreading layer. Also, a thin epitaxial layer 104-1 may still be maintained to be used in the next step processes. In either of the examples described above, the conductive metal 108 of the vias are connected to the conductive layer 109 which connects to the topside of the micro-LEDs through 104-2 or directly to the tops of the micro-LEDs to provide a means for routing the electrical connections from the topsides of the micro-LEDs to the bottomside of the micro-LED display which may be later connected to driving circuits (not shown).

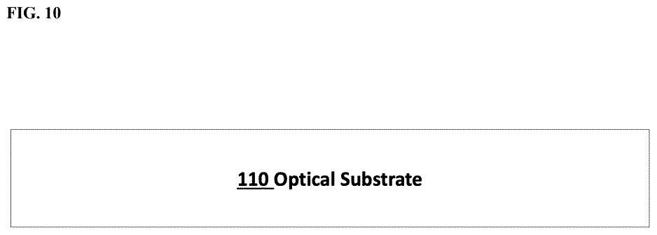

In conjunction with fabricating the micro-LEDs described above, optics are also fabricated for bonding to the micro-LEDs. For example, FIG. 10 illustrates an optical substrate 110 that may be made from glass. The refractive index of the optical substrate may be chosen to enhance the light extraction, light guiding and light coupling properties.

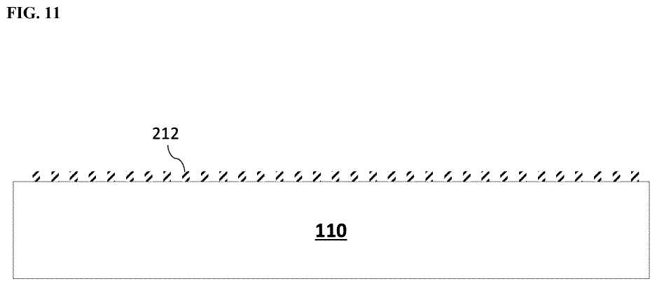

FIG. 11 shows the optical substrate with optical elements 212 created thereon. The optical elements may include homogenizing lenses, collimating lenses, meta-lenses, diffractive optical elements, concave, convex lenses or the like. The optical elements may be made by patterning a coated layer (such as TiO₂ or a-Si:H), by etching and patterning the surface of the optical substrate, or by some photo-definable polymers. These optical elements may, for example, be designed for directional guiding of the light, doubling the emission point without increasing the number of pixels, or for reducing the reflection.

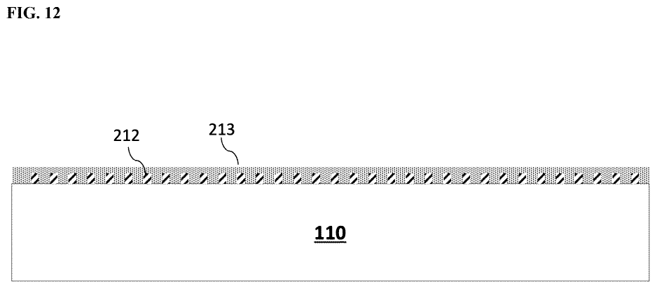

FIG. 12 illustrates the optical substrate and optical elements may coated with a protective layer 213. This layer 213 may be used to protect the optical elements 212 during handling. Also, this layer may be used to optically tune the optical elements, for example, for selective wavelength functionality. This layer may be made from optical polymers and by using spin or blade coating techniques.

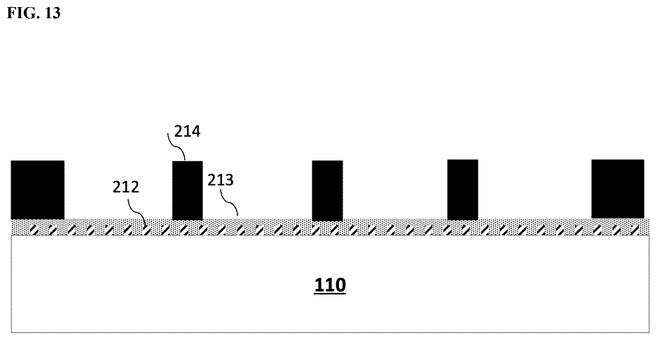

FIG. 13 illustrates light blocking structures referred to as black matrices 214 created on the optical element substrate. These black matrices may be used to reduce the crosstalk between the neighbor LED emission regions and reduce the reflection of the environment light from the display surface. The black matrices may be originally photo-definable (photoresist) material that may be patterned using photo lithography techniques. In addition, thermal or UV curing may be implemented after patterning to increase their hardness.

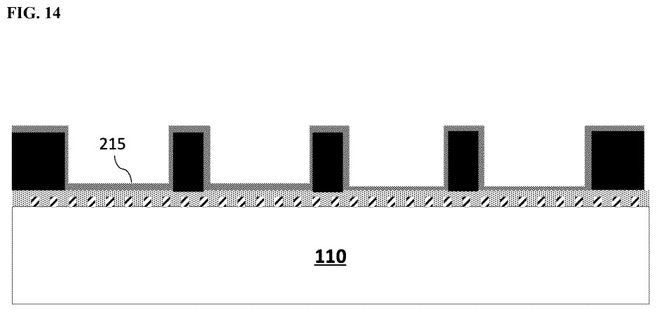

FIG. 14 illustrates the reflective single or multi-layer coating 215 on the black matrices and optical substrate. The layer 215 may be made from a stack of different metals with a combination of properties such as adhesion, reflection and anti-oxidation, or may be a stack of dielectrics which are selectively reflective in a specific wavelength. Also, the reflective layer may be used for photo-recycling.

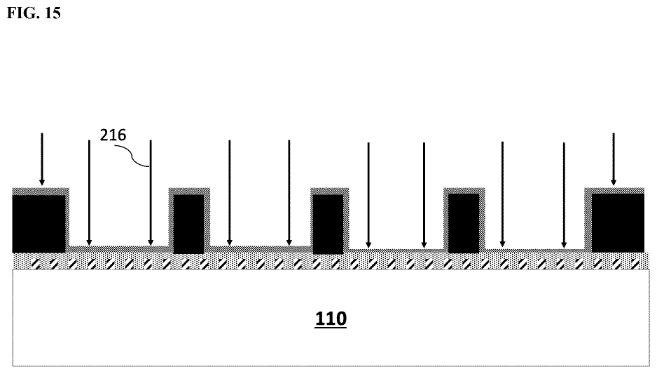

FIG. 15 illustrate the directional etching process 216 to remove the reflective layer from the unwanted areas. The directional etching process 216 may employ ion milling, laser ablation or other techniques to etch portions of the reflective layer. Portions of the reflective layer be removed from the horizontal surface where the reflective layer may be bombarded by ions or laser beam. A live reflection measurement may also be employed during the etching process to stop the etching after reflective layer removal.

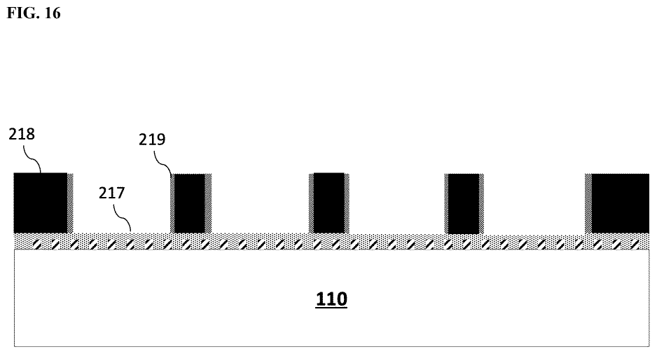

FIG. 16 illustrates an example where the reflective layer 219 remains on the sidewall of the black matrices after the etching process. The black matrices' topside 218 and topside 217 of the optical substrate are exposed. The sidewall angle of the black matrices is beneficial to control in order to maintain the sidewall intact. Other photoresists such as negative photoresist SU8 which provide high aspect ratio after lithography process may be used for this process instead of black matrices.

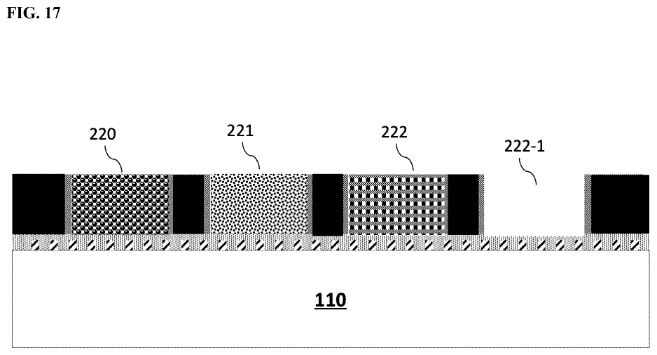

FIG. 17 illustrates the optical substrate where the color conversion structures 220, 221, and 222 are fabricated at the space between black matrices. Color conversion structures may be tuned to a specific color scheme such as red (R), green (G) and blue (B) for producing a pixel of a desired color when the light from the RGB regions is combined. For example, the RGB light at emitted from structures 220, 221 and 222 may mix at specific intensities to produce a desired color of a display pixel depending on the desired control of the display (e.g. the desired data transmission). These color-conversion materials may be made from quantum dots, phosphorus materials, nanowires or any other material that may down-convert the light to longer wavelengths. Depending on the desired thickness, several techniques may be used to coat a thick photo-definable color-conversion layer on the optical substrate such as spin coating, inkjet or aerosol printing, or blade coating. Photolithography processes and development may be used to pattern the color-conversion layer in the right place and remove the excess material. Each color may be processed separately. In FIG. 17, the rightmost space between the black matrices is not filled with a color conversion structure and therefore the light emitted from the micro-LED in that region is not color converted.

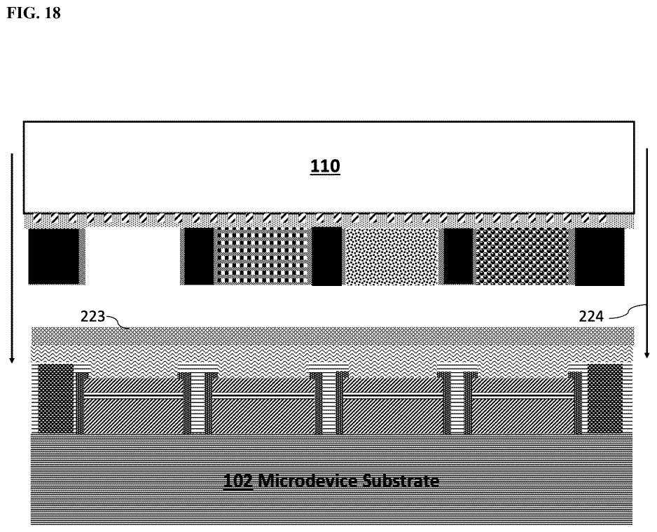

FIG. 18 illustrates the alignment of the optical substrate (with color-conversion layers) and a micro-device substrate (with micro-LEDs thereon). Each color-conversion layer is aligned to a corresponding micro-LED. In another example, one color-conversion cell may also cover two or more micro-LEDs for achieving redundancy. An optically clear adhesive (OCA) 223 may be used to attach the color-conversion layer to the micro-LED structure. The OCA 233 may be enhanced by further thermal or UV curing to improve its adhesion and mechanical strength. The OCA may be chosen to filter or reflect a range of the light spectrum. The two layers may be bonded together using a force 224 that may be higher than the force of gravity due to the weight of the optical substrate.

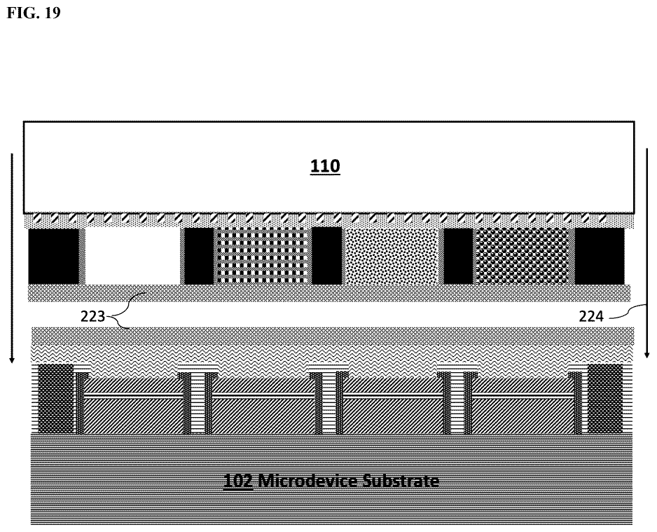

FIG. 19 illustrates the alignment of the optical substrate (with color-conversion layers) and micro-device substrate (with micro-LEDs thereon). The OCA 223 may be coated on both the micro-LED and optical substrate sides. In this case, a thinner OCA may be used, and the assembly process may be performed in vacuum. By applying force 224, the two surfaces may be bonded together.

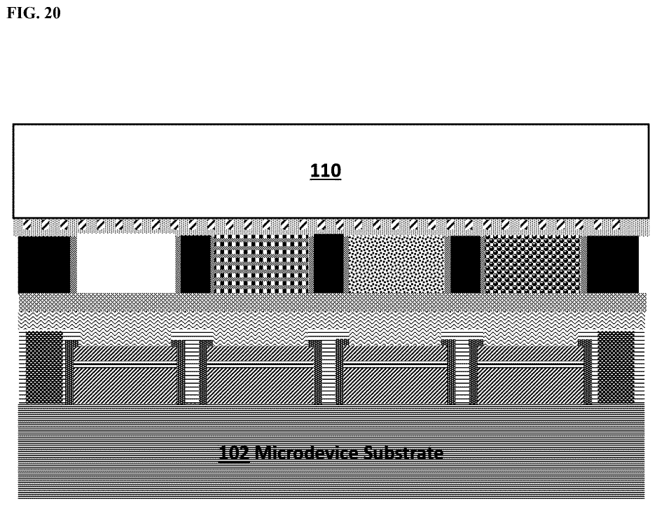

FIG. 20 illustrates the optical substrate and micro-device substrate in FIGS. 18 and 19 after integration. As shown, the two substrates with active and passive elements thereon are monolithically bonded. This package may proceed to further post curing to obtain a desired mechanical strength.

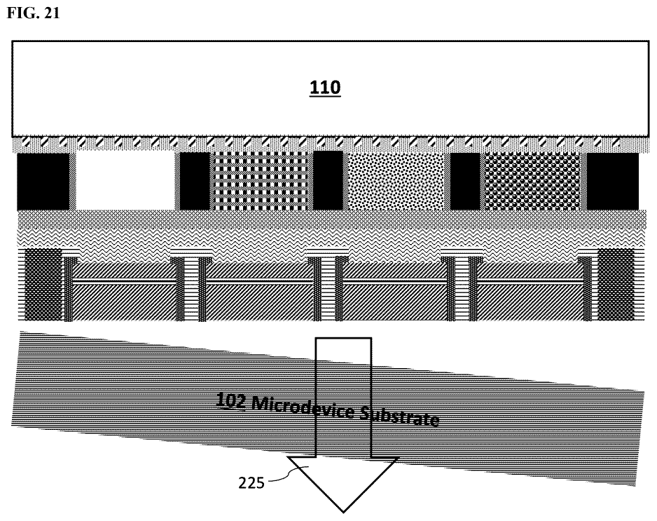

FIG. 21 illustrates the substrate removal process. If the micro-device substrate 102 is made from silicon or silicon carbide (SiC), processes such as chemical mechanical polishing (CMP), other polishing techniques, grinding and etching may be used to remove the substrate. If the micro-device substrate 102 is made from sapphire, processes such as laser lift-off, epitaxial lift-off may be used to remove the substrate.

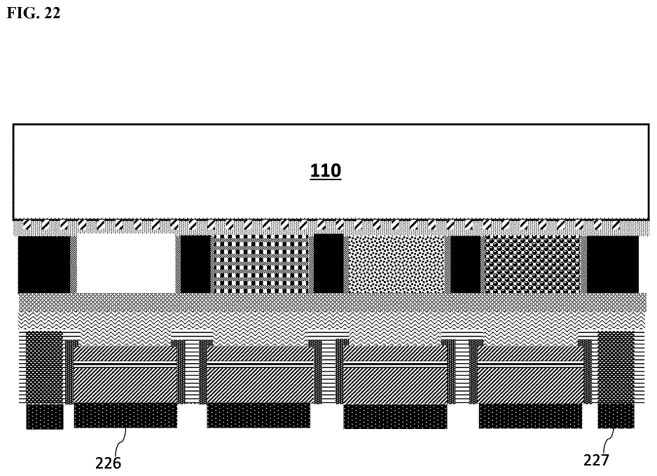

FIG. 22 illustrates electrodes or pads 226 and 227 created on the backside (e.g. bottomside) of the micro-LEDs and vias. After removing the micro-device substrate 102, the epitaxial layer backside may be exposed. Further processes such as dry or wet etching may be implemented to finish the pixilation process or access to vias. For creating electrodes and pads, processes such as metallization, lithography, electroplating, or etching may be used. The micro-LED back-contact and bonding electrode 226 may be created in one step. Both 226 and 227 may be made from hard materials such as copper, gold, silver or soft solders. The micro-LED back-contact and bonding electrode may also be a combination of several materials coated at the same time or created as a multi-layer structure. In either case, bonding pads 227 provide electrical contact with the topside common electrode of the micro-LEDs, while bonding pads 226 provide electrical contact with the individual and separate bottomside electrodes of each of the micro-LEDs. This allows power to be applied between 227 and selected bonding pads 226 to illuminate one or more desired micro-LEDs according to the control of the display.

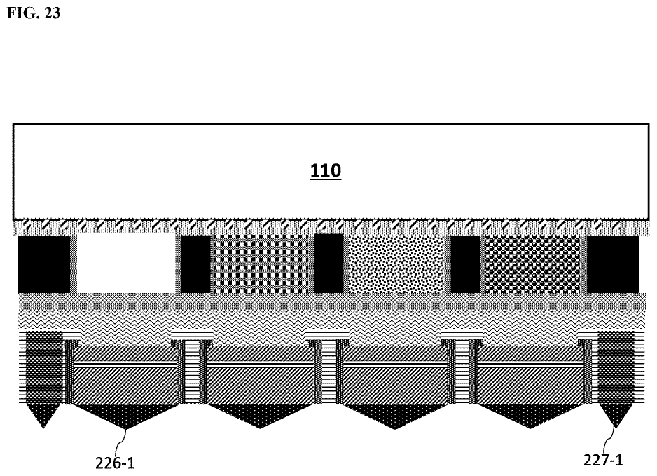

The bonding pads in FIG. 22 may be bonded to bonding pads of driver circuits (not shown) using conductive cement, solder or the like. However, the bonding pads may be shaped in a manner to pierce the bonding pads of the driver circuits. For example, FIG. 23 illustrates the structure when the backside electrodes 226-1 and 227-1 (or bonding electrodes) are created with sharp tips. These sharp tips may help the bonding process to the next substrate by penetrating driver circuit bonding pads. In order to produce sharp tips, pattern coating, and gradient lithography of metal lift-off processes may be used.

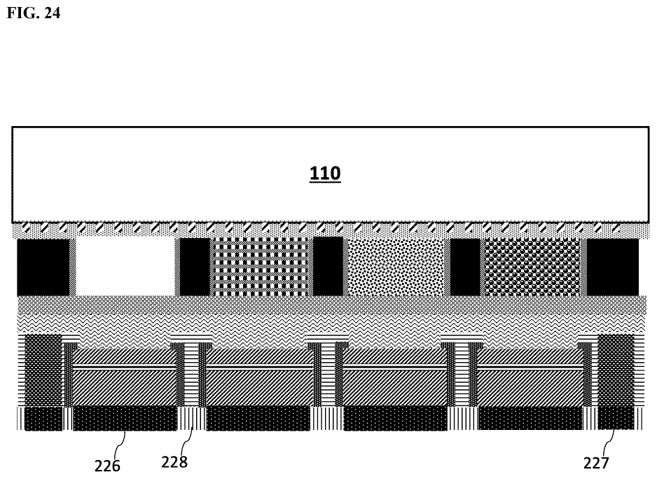

In FIG. 24, the space 228 between bonding electrodes 226 and 227 may be filled with an oxide layer, polymer or another agent that may help in hybrid bonding where the oxide layer 228 is bonded to an oxide layer (not shown) of the driver circuit substrate and the LED bonding pads 226/227 are bonded to driver circuit bonding pads (not shown). If a polymer like a polyimide or BCB is used, it may be partially cured to keep the shape during further processes. If an oxide layer is used, an additional polishing process may provide a smoother and flatter surface which is beneficial in the next bonding process. The oxide layer may be coated before bonding electrode deposition and patterning.

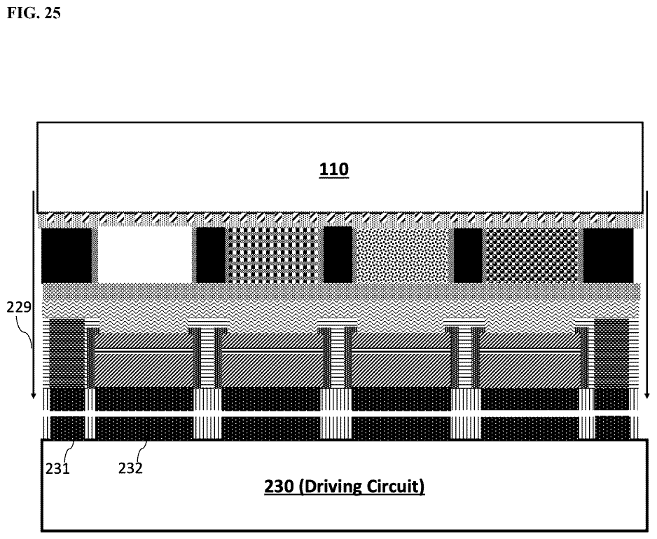

FIG. 25 shows the alignment of the micro-LED bonding pads and the via bonding pads to bonding electrodes 231 and 232 of the driving circuit substrate 230. An external force 229 and heat (not shown) may be used during the bonding process along with conductive cement, solder or the like. A wafer level integration process may be used for both electrical and optical assembly.

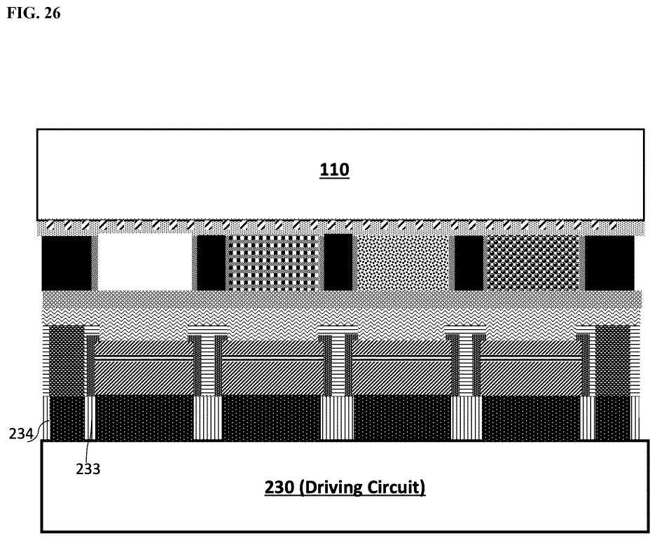

FIG. 26 illustrates a complete micro-LED display after assembly. As a hybrid bonding technique, a metal-to-metal 234 and dielectric-to-dielectric 233 bonding process may be used to ensure both electrical and mechanical stability. In addition, thermal curing may be used to reduce contact resistance and further enhance mechanical stability.

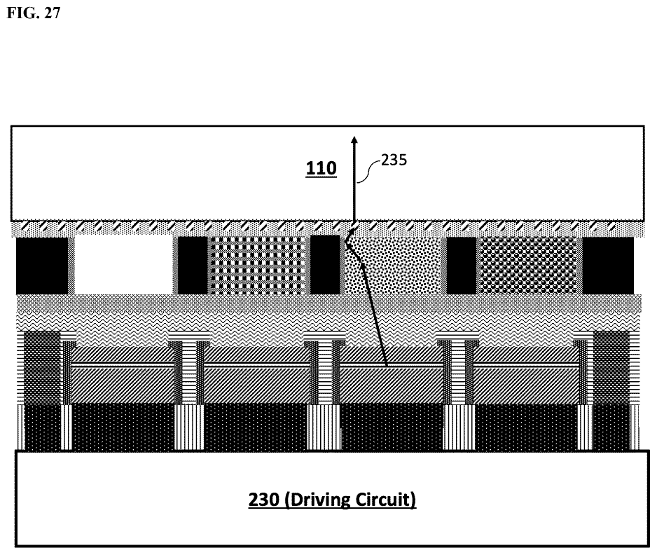

FIG. 27 shows an example of a photon 235 (or light) passing from generation at the quantum wells in a micro-LED, passing through the color-conversion layer, reflecting from the cell sidewalls of the color conversion layer, and guided in a direction by optical elements out the emission opening (topside) of the display in a homogenized and collimated direction. As described above, an objective of the current design may be directional emission of the photons to couple the photons into another waveguide or the pupil of the user. Thus, the device is able to harvest, homogenize and collimate rogue photons in a manner that directs them towards another waveguide (e.g. fiberoptic transmission system) or the pupil of the user (e.g. AR/VR display).

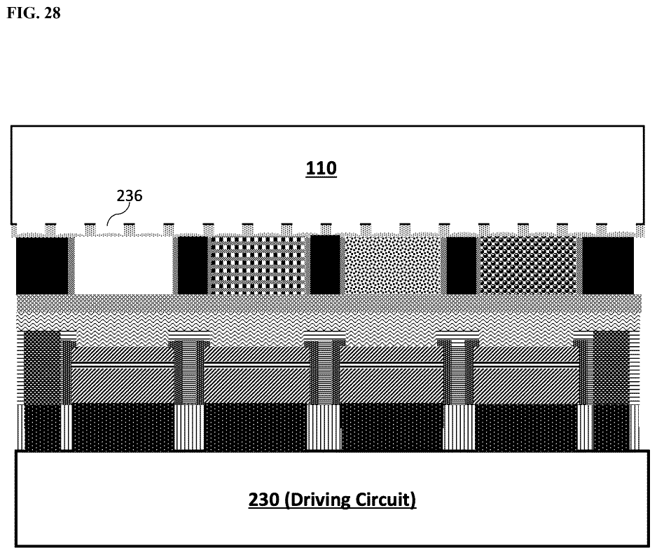

FIG. 28 shows a micro-LED display where the optical elements 236 may be beam homogenizers, collimators, shack-hartmann arrays, or diffractive optical elements. Any type of optical element is possible to manipulate photons in a desired manner for a particular application.

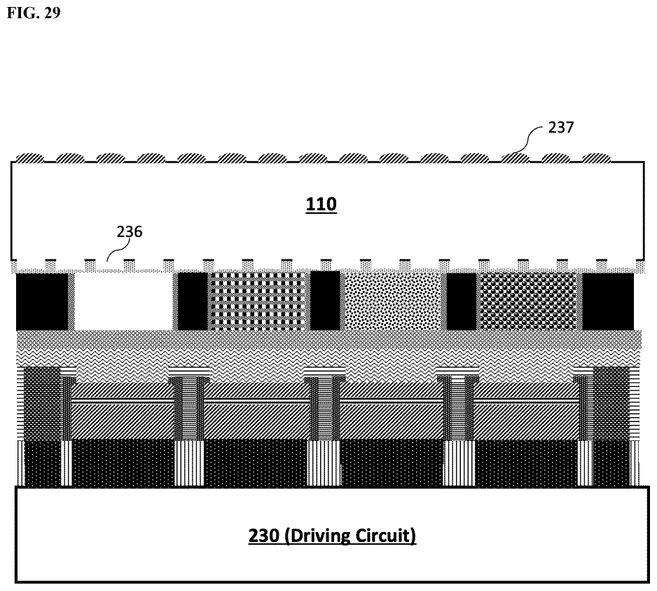

In addition to the optics shown in FIGS. 27 and 28, the micro-LED display may utilize a second layer of optics 237. For example, FIG. 29 illustrates a micro-LED display with optical substrate 110 with optical elements on both sides of the substrate to create dual-layer optics. On one side optics 236 may be used as a homogenizer and on the other side optics 237 may be used for shaping the beam. The topside optical elements 237 may be an array of optical micro-lenses or meta-lenses. The thickness of the optical substrate may be chosen in order to manipulate the light in the desired manner. This dual-layer optic configuration may be beneficial in use cases such as fiber optic transmission where the light is homogenized and collimated to a waveguide. The lens group on top of each pixel or group of pixels might be different from the adjacent pixel and depends on the wavelength and light properties.

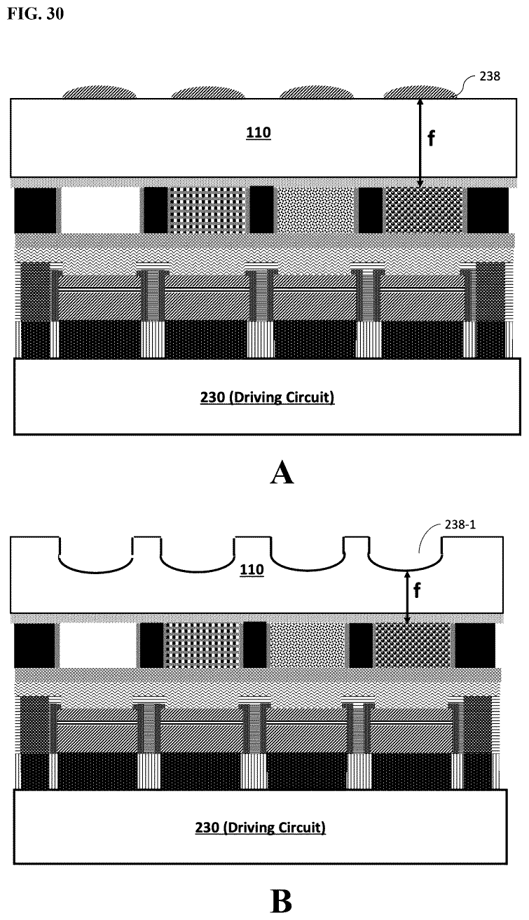

FIG. 30A illustrates a micro-LED structure with micro-lens elements 238 on the topside of the optical assembly. The optical assembly may be performed by wafer-level packaging technology. The size and curvature of the micro-lenses may be designed to achieve maximum collimation or other optical results for manipulating the photons emitted from the micro-LED display.

FIG. 30B illustrates a micro-LED structure with micro-lens elements 238-1 on the topside of the optical assembly. The micro-lens 238-1 may be formed by recessing the glass topside to create diffractive optical elements or to save space.

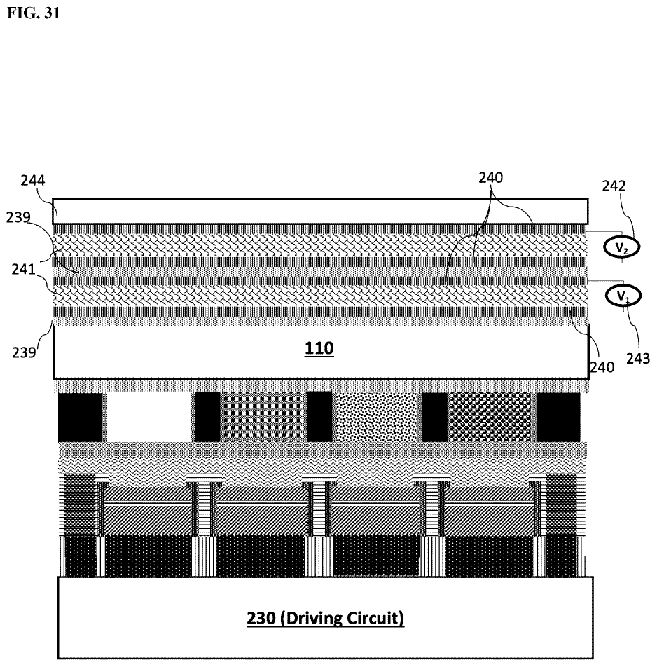

FIG. 31 illustrates a micro-LED display integrated with liquid active crystal optics. A polarizer 239 may polarize the output photons. Liquid crystal material 241 may be included between alignment layers 240 to control the crystal orientation. The alignment layer may be created by a controller (not shown) that applies external voltages 242 and 243 to control the crystal orientation and tune the optical functionality of the lens. A top optical glass 244 may be incorporated into the device structure to protect the surface and may provide additional optical properties such as anti-reflection. Controlling the direction of the light or changing the focal length may be a few applications for the integrated liquid crystal lens.

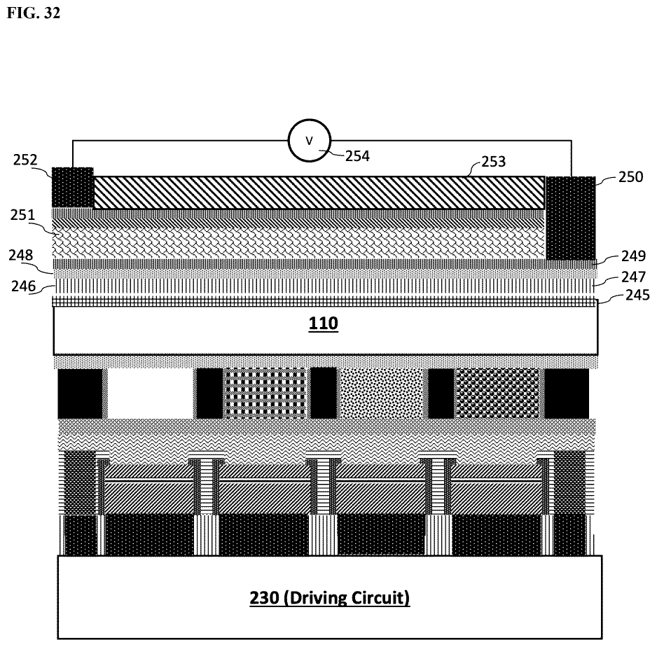

FIG. 32 illustrates another architecture for assembling active liquid crystal optics on a micro-LED display. Liquid crystal functional optics are fabricated in a wafer-level process and may be integrated on top of the display. An optically clear adhesive (OCA) 245 may be used to assemble the liquid crystal optics. An optical glass that may be a polarizer 246 for tuning the output light polarization. The liquid crystal is sandwiched between two alignment layers 248 and transparent conductive layer that may be made from ITO 249. Two electrodes 250 and 252 apply the voltage from an external source 254 to ITO 249. The top glass 253 may also have additional optical functionality.

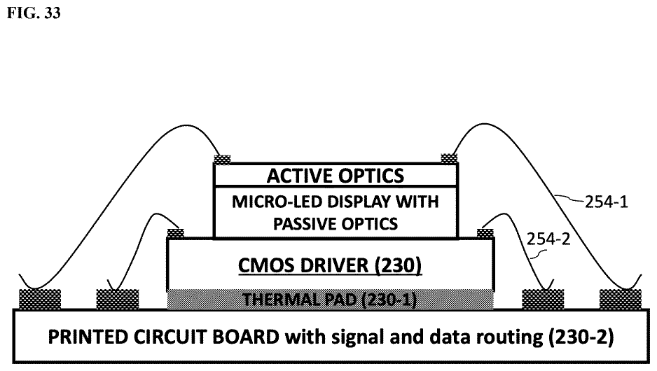

FIG. 33 illustrates the system structure of a micro-LED display 230-1 integrated with active optics 230-2 and their assembly onto a PCB 230-3 which may deliver both data signals and power through wires 254-1 and 254-2. Active optics and the micro-LED display are biased and driven separately. The information and feedback from the environment or an eye-tracking system may be used to actively tune the optical properties of the emitted photons. Although not shown, a display controller (e.g. processor, memory, etc.) of a device (e.g. optical transmitter, AR/VR goggles, etc.) may be connected to the CMOS driver and to the active optics to control the output of the micro-LEDs and the manner in which the light output by the micro-LEDs is manipulated. This control is generally performed by the controller applying data/voltage signals to the driver and to the active optics via wires 254-1 and 254-2, each of which may represent one or more wires. The display controller may be fabricated on substrate 230-3 or a different substrate that is electrically connected to the micro-LED display.

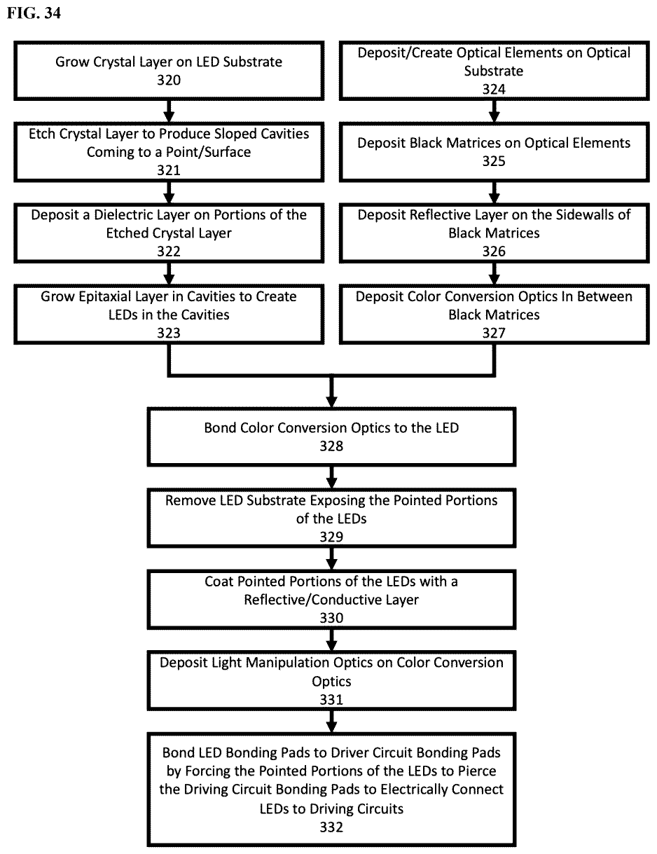

FIG. 34 illustrates the overall fabrication process of a micro-LED display with sloped LEDs (e.g. LEDs with sharp tips). Generally, the LEDs and optics are fabricated separately and then bonded together to form the micro-LED display.

Steps 320-323 describe the fabrication of the LEDs. Specifically, in step 320 a crystal layer is grown on an LED substrate (e.g. silicon), in step 321, the crystal layer and substrate are etched to produce cavities having desired sloped shapes that come to points (e.g. sharp tips), and in step 322, a dielectric layer is deposited on portions of the etched crystal/substrate. In step 323, an epitaxial layer is grown in the cavities to create LEDs having a sloped shape that come to a point (e.g. the pixels take the shape of the cavities).

Steps 324-327 describe the fabrication of the optics. Specifically, in step 324, the optical elements (e.g. lenses for light collection, homogenization etc.) are deposited on the optics substrate, and in step 325, black matrices are deposited on the optical elements to block regions of the optics from receiving light. Then, in step 326 reflective material is deposited on portions of the black matrices, and in step 327 color conversion optics are deposited in between the black matrices.

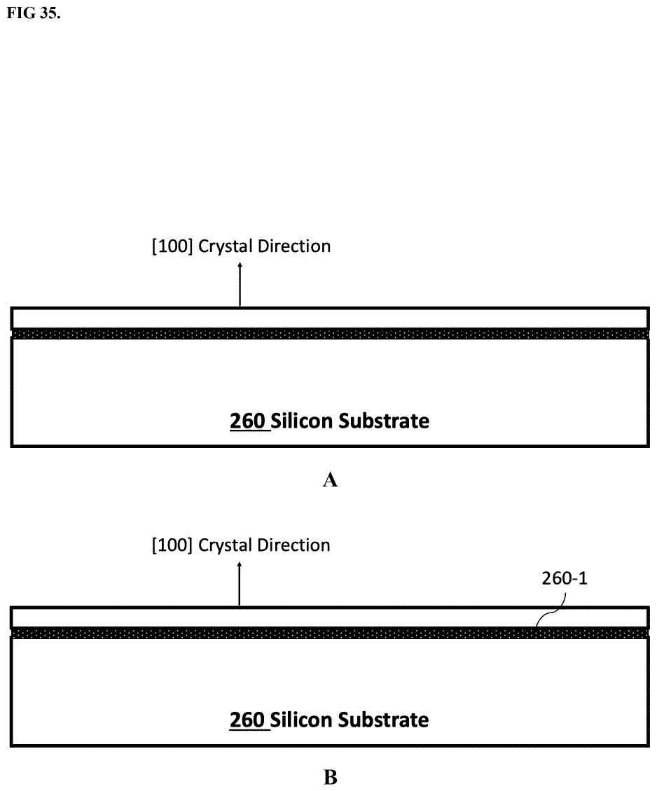

Steps 328-332 describe the bonding of the micro-LEDs with the optics. Specifically, in step 328, the color conversion optics are bonded to the micro-LEDs, and in step 329, the LED substrate is removed. Then, in step 330, the pointed portions (e.g. sharp tips) of the micro-LEDs are coated with a reflective/conductive layer, and in step 331, additional light manipulating optics (e.g. lenses for light collimation, focal point manipulation, etc.) are deposited on the color conversion optics. In step 332, the LED bonding pads are then bonded to the driver circuit bonding pads by forcing the pointed portions (e.g. sharp tips) of the LEDs to pierce the driving circuit bonding pads thereby electrically connecting the LEDs to the driver circuits. An adhesive may also be applied between the points of the micro-LEDs to further increase mechanical stability. The steps described in FIG. 34 will now be described in further detail with respect to FIGS. 35-63 below.

FIG. 35A illustrates a silicon substrate 260 with [100] crystal orientation on top. The wafer may be an SOI wafer with an oxide layer 260-1 and a silicon layer on top of it as shown in FIG. 35B.

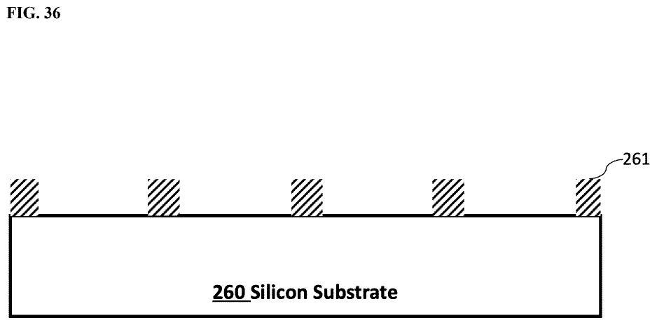

FIG. 36 shows a dielectric 261 layer patterned on the silicon substrate. The dielectric may be made from silicon nitride (SiNₓ) or silicon oxide (SiO₂). The thickness of the dielectric layer may be tuned according to the epitaxial layer structure requirements. Processes such as low-pressure chemical vapor deposition (LPCVD), Plasma enhanced chemical vapor deposition (PECVD), Oxidation, lithography, and etching process may be used for this purpose.

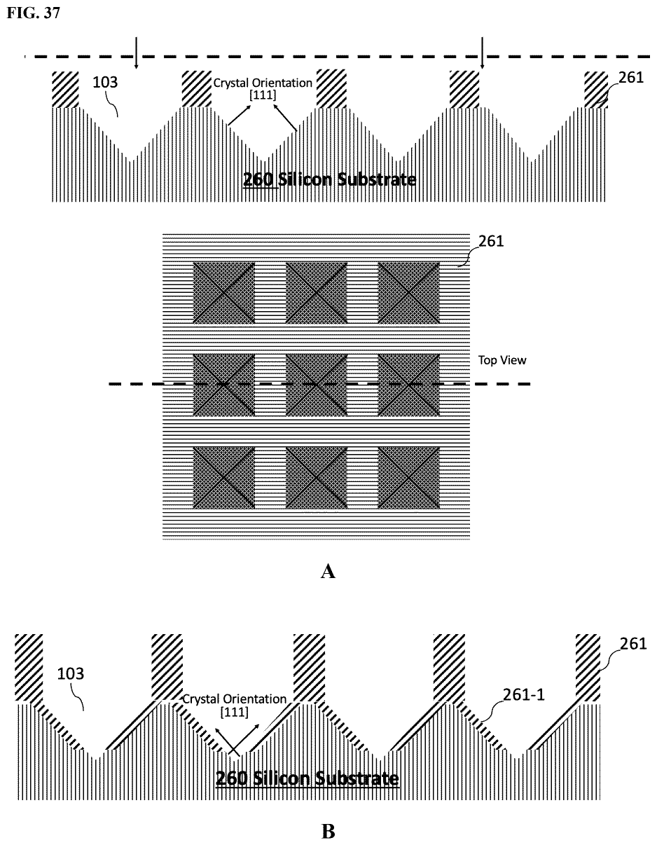

FIG. 37A shows the silicon substrate 260 after etching with potassium hydroxide (KOH) or tetramethyl ammonium hydroxide (TMAH) to expose the [111] crystal planes. The etched area 103 cavity may be used for the next step of crystal growth and self-aligned pixel formation. A top view is also shown in FIG. 37A where the topsides of the cavities are rectangular at the top and pointed (e.g. sharp tips) at the bottom.

FIG. 37B illustrates the silicon substrate 260 after etching and use of second passivation layer 261 and 261-1 deposition and opening. The second dielectric (such as SiNₓ or SiO₂) may be made by a PECVD, LPCVD coating or thermal oxidation of the wafer. The second dielectric at the bottom of the etched region may be etched away using lithography and etching processes. The bottom region 261-2 may be used as the seed layer to grow the epitaxial structure of the LEDs. Passivation layer 261-1 is reflective and is useful in reflecting rogue photons emitted downward from the active region of the micro-LED (not shown).

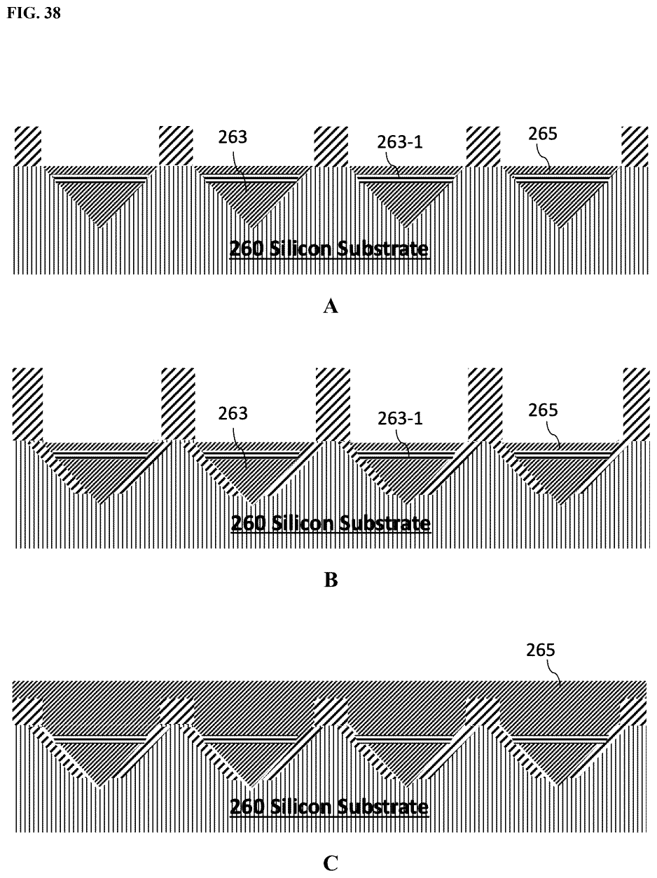

FIG. 38A illustrates the epitaxial layer of the LEDs grown inside the etched area and on the [111] crystal orientation in a structure without passivation layer 261-1. The epitaxial layer may contain n-region 263, active region (QWs) 263-1 and p-region 265. The epitaxial layer height (thickness) may reach the surface plane of the silicon wafer or may be thicker. In this epitaxial structure, the active region 263-1 is inside of the groove and in the sloped region. The active region 263-1 may touch the silicon sidewalls, or there may be a thin epitaxial layer interfaced with the active region and silicon sidewalls. In this case, the thin epitaxial layer may be a removed etched layer to prevent short-circuit between the adjacent micro-LEDs.

FIG. 38B illustrates the epitaxial layer grown on the patterned silicon substrate in a structure with a passivation layer 261-1. The sidewall of the epitaxial layer is mostly interfaced with the dielectric layer 261-1 and the active region is inherently passivated. FIG. 38C illustrates a micro-LED structure also with a passivation layer 261-1 where the top epitaxial layer 265 may be overgrown and create a common electrical contact region for all the micro-LEDs. Epitaxial layer 265 may result in a highly doped semiconductor.

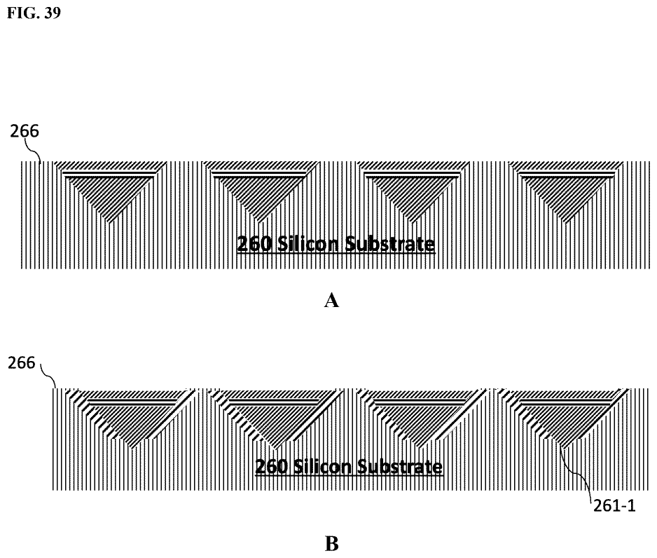

FIG. 39A illustrates the silicon substrate 260 and micro-LED epitaxial structure after removing the dielectric layer (passivation layer) 261. The top surface 266 of the silicon is shown as being exposed.

FIG. 39B illustrates the silicon substrate 260 and micro-LED epitaxial structure in a structure after removing the dielectric layer 261 from region 261-1. The dielectric around the micro-LED epitaxial structure remains intact. The dielectric layer 261 may also be maintained for the next step of the process.

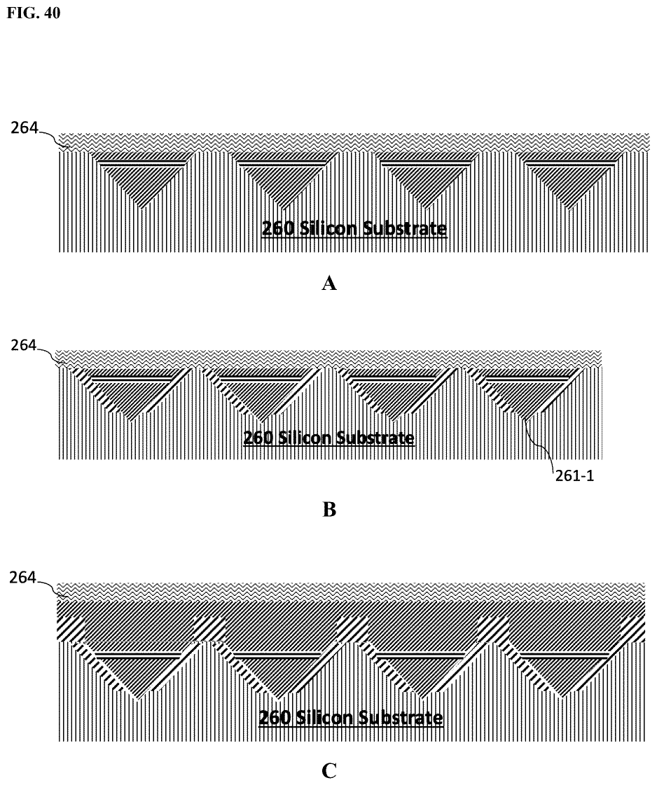

FIG. 40A illustrates the common anode layer 264 coated on the micro-LED structure in a structure without passivation layer 261. This layer may act as current spreading layer and as an ohmic contact to the p-region of the LEDs.

FIG. 40B illustrates the common anode layer coated on micro-LEDs surrounded with a dielectric in a structure where passivation layer 261 is removed from region 261-1 before epitaxial growth. FIG. 40C illustrates the common anode 264 contact coated on the overgrown epitaxial structure in a structure where passivation layer 261 is removed from region 261-1 before crystal growth. Layer 264 may act both as a current spreading layer and ohmic contact.

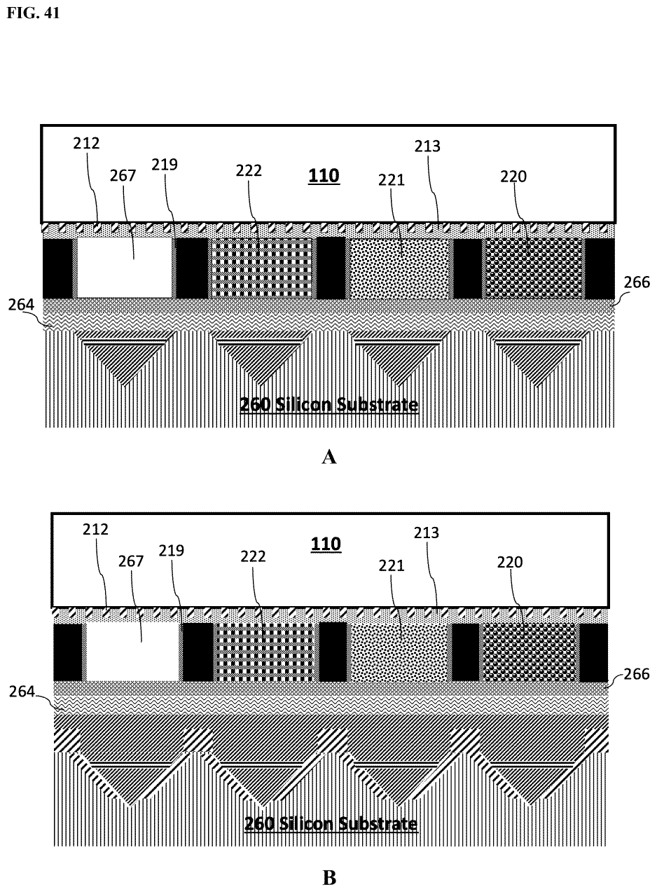

FIG. 41A (structure without passivation layer 261) illustrates the micro-LED structure integrated with an optical substrate 110 which may contain color conversion structures 220, 221, 222, 267 and optical elements 212 such as micro-lenses. An optical clear adhesive 266 may be used to bond two wafers together. Additional thermal curing may be implemented to cure the OCA and improve mechanical stability. FIG. 41B (structure where passivation layer 261 is removed from region 261-1 before epitaxial growth) illustrates the optical substrate 110 and its elements integrated into the micro-LED structure with an overgrown epilayer and dielectric layer 261 and 261-1 surrounding the micro-pixels.

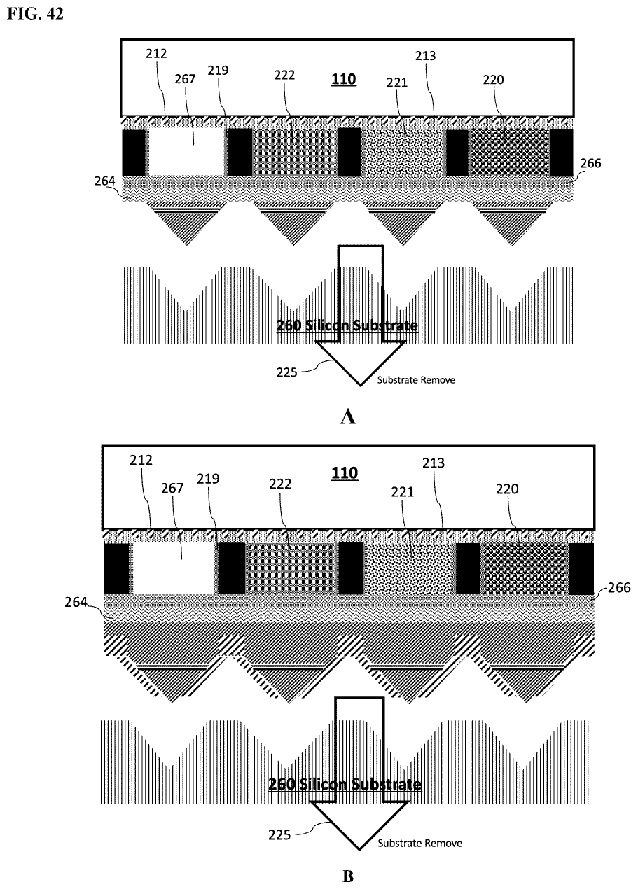

FIG. 42A (structure without passivation layer 261) and 42B (structure where passivation layer 261 is removed from region 261-1 before epitaxial growth) illustrate the substrate removal process. Silicon substrate 260 may be thinned using grinding, and polishing processes and be removed completely with chemical or physical etching. Dry or wet etching may be used in order to remove any residue or thin layer of the silicon substrate 260. After silicon substrate removal, the micro-LEDs are transferred onto the optical substrate.

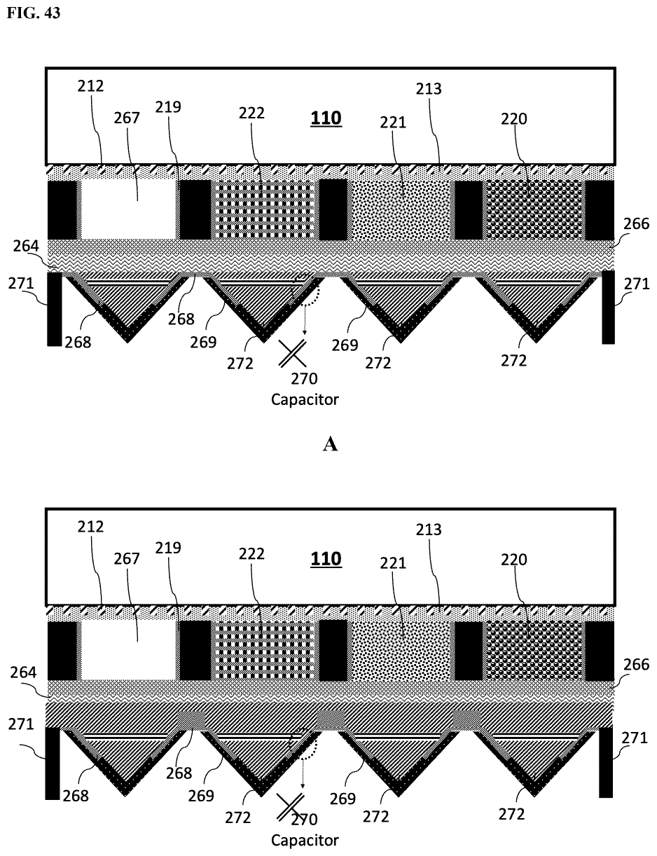

FIG. 43A (structure without overgrown epitaxial layer) and 43B (structure with overgrown epitaxial layer) illustrate the micro-LED backside processing which may create an ohmic contact 269 connected to the micro-LEDs n-region 272. An electrode 271 may be connected to the common anode contact 264. Since the backside electrode surrounds the micro-LEDs, a self-aligned capacitor 270 close to the active region is created which may be used to deplete the area from electrical carriers. A dielectric layer 268 may be coated and patterned to prevent a short circuit between anode and cathode electrodes. In the dielectric where the cathode structure is surrounded with an overgrown epitaxial layer, additional processes such as dielectric coating and patterning may not be implemented. The dielectric layer in these structures is self-aligned and prevents any potential short-circuit.

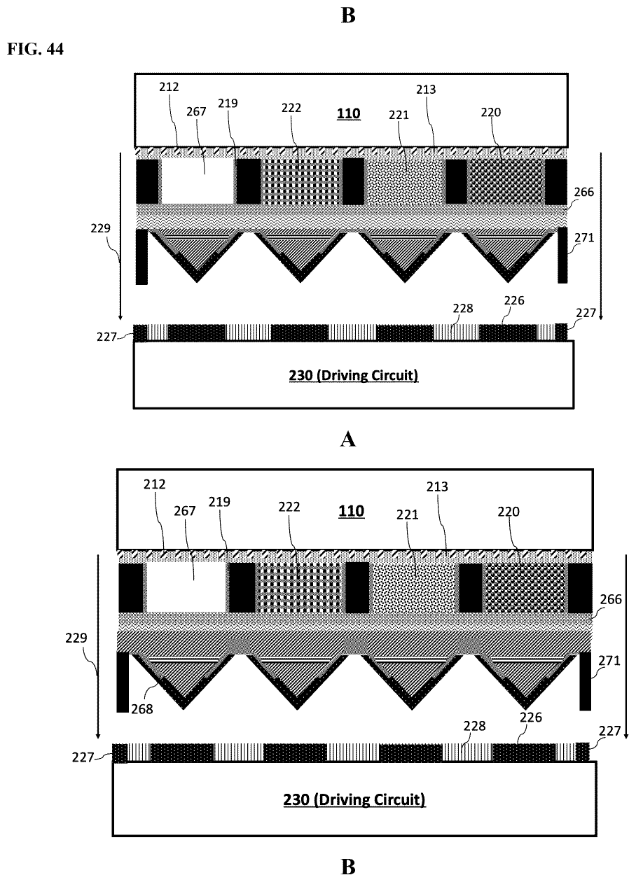

FIG. 44A (structure without overgrown epitaxial layer) and 44B (structure with overgrown epitaxial layer) illustrate the alignment of the micro-LED contact pads and the driving circuit 230 contact pads 226 and 227 in order to drive micro-LEDs electrically. A dielectric 228 such as polymer or oxide may fill the space between the electrode on the CMOS substrate. The wafer-level alignment process may be used in this step. A single pixel or a group of pixels may be bonded to one driving circuit pad.

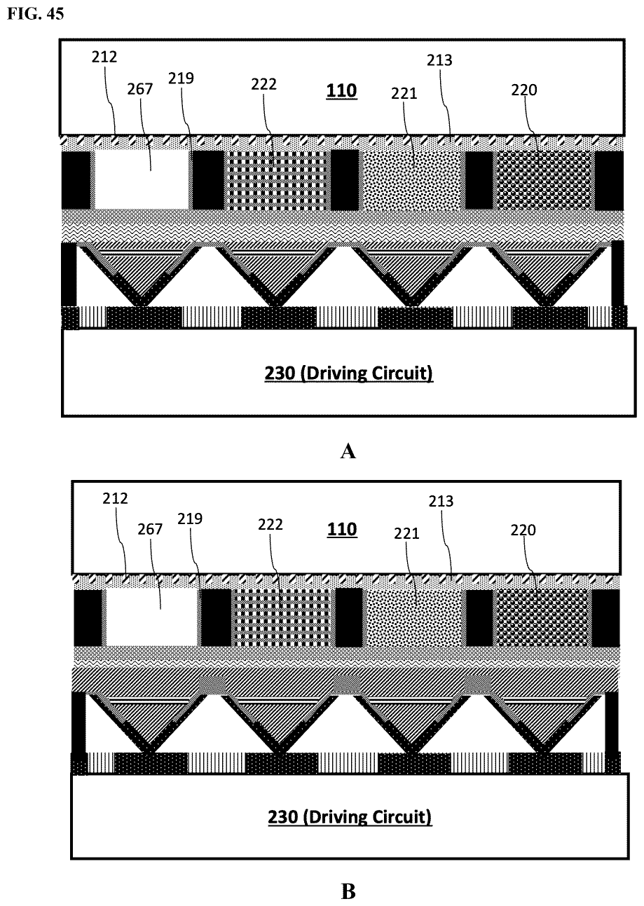

FIG. 45A (structure without overgrown epitaxial layer) and 45B (structure with overgrown epitaxial layer) show the micro-LED display after the integration of micro-LEDs to the driving circuit 230. Driving circuit 230 may be fabricated based-on CMOS technology. The sharp tips of the micro-LED backside help to make reliable contact without requiring a high force and risking contamination. In addition, the sharp electrode tips may penetrate easily into any oxide on the driving circuit bonding pads, and as a result of the integration, the process is less sensitive to the metal surface quality.

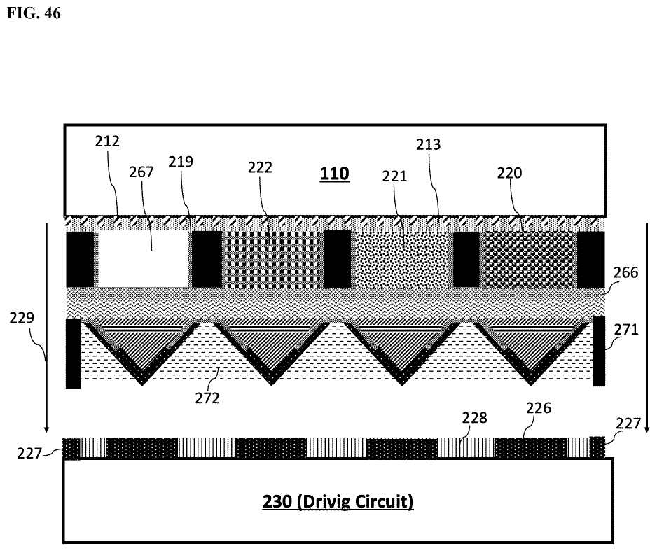

As shown in FIG. 46, the space between the micro-LEDs may be filled with a polymer (or oxide) 272. The space between the driving circuit pads 226 and 227 may also be filled with a polymer (or oxide) 228. When aligning two substrates, the dielectrics may be aligned together. If a polymer is used as a filler, during the heat treatment, the polymer 272 coated on the optical substrate 110 may become soft and provide the opportunity for contact/bonding with the surface of the driving circuit substrate 230.

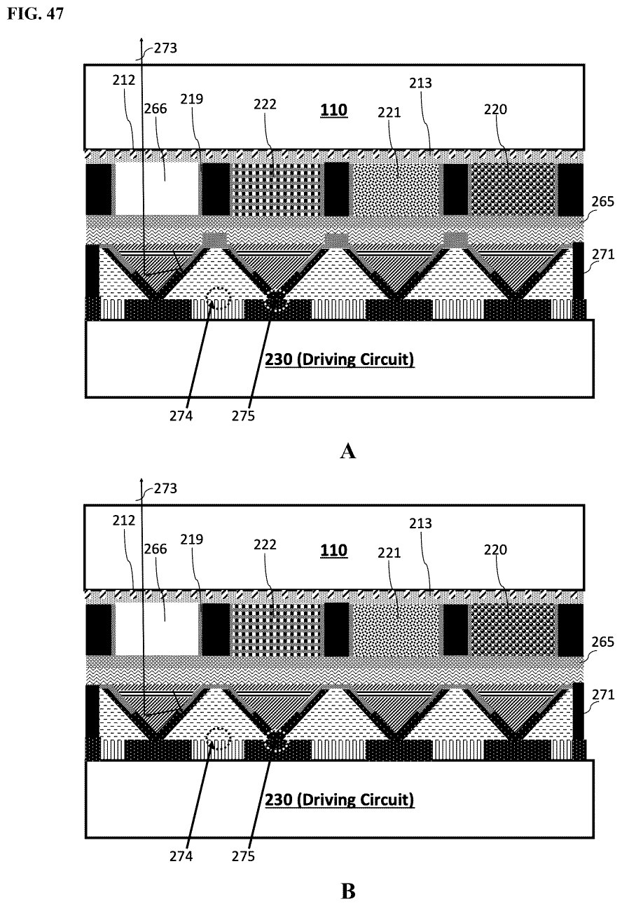

FIGS. 47A and 47B show the micro-LED display after assembly. The sharp tip of the back electrodes may be penetrated at 275 into the pads on the driving circuit substrate 230. As result, a lower bonding temperature may be implemented to bond these two substrates. In addition, the polymers (or oxides) are bonded at 274 which provides higher mechanical strength. An example of a photon path 273 is shown in both FIGS. 47A and 47B. Because of the sidewall angle of the micro-LED and the reflective backside electrode, the light may be reflected upwards which may increase the final light extraction efficiency and save operation power.

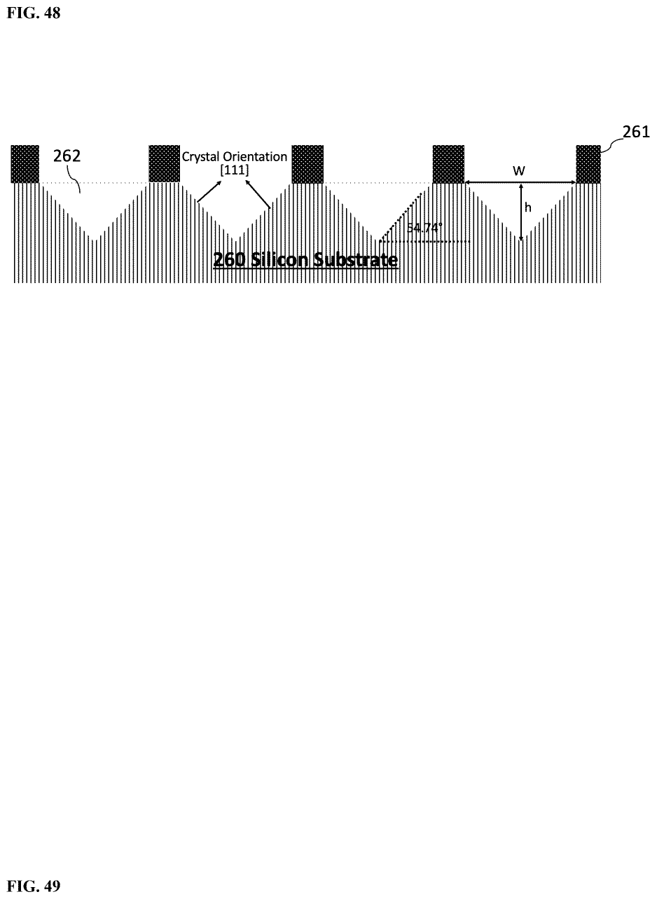

FIGS. 48-63 show another example embodiment of creating micro-LEDs with pointed bottoms (e.g. sharp tips) where the active region of the LEDs is grown higher than the active regions shown in FIGS. 35-47. For example, FIG. 48 illustrates a silicon substrate 260 with dielectric masks 261 and etched to expose the [111] crystal planes. Area 262 is the groove exposed in the etched region. The etch angle of the crystal planes may be set to increase optical efficiency (e.g. 54.74°).

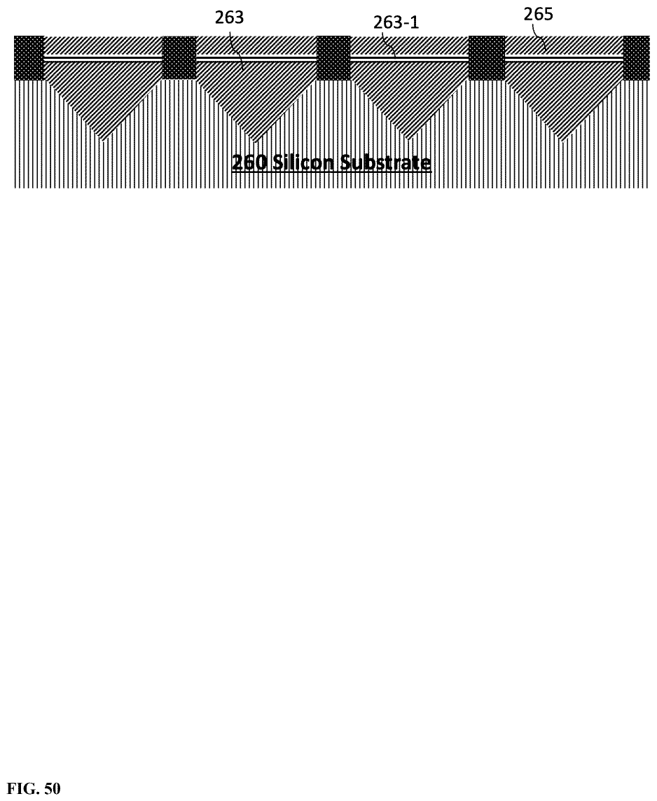

FIG. 49 illustrates the micro-LED epitaxial layer grown inside the groove structure. The quantum wells producing the active region 263-1 may be grown at a position higher than the silicon substrate surface 260. The active region may be interfaced with a dielectric layer that may provide a self-aligned passivation layer.

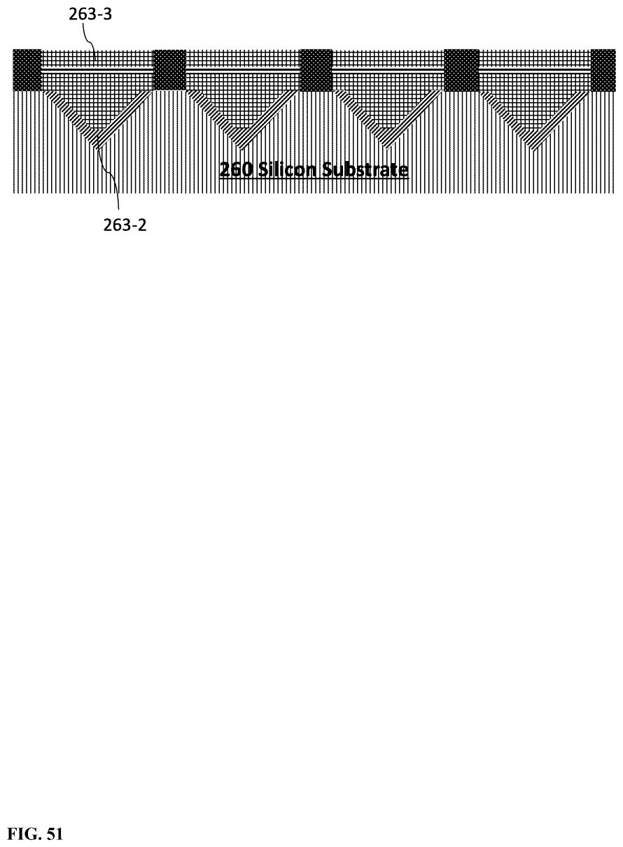

FIG. 50 illustrates the micro-LED epitaxial layer which may contain various phases of crystal orientation. The epitaxial layer 263-2 interfaced with silicon substrate may have different crystal orientations than the epitaxial layer 263-3 on top of the structure. The crystal orientation change may occur when different crystal planes coalesce, and the epitaxial layer grows in a new direction.

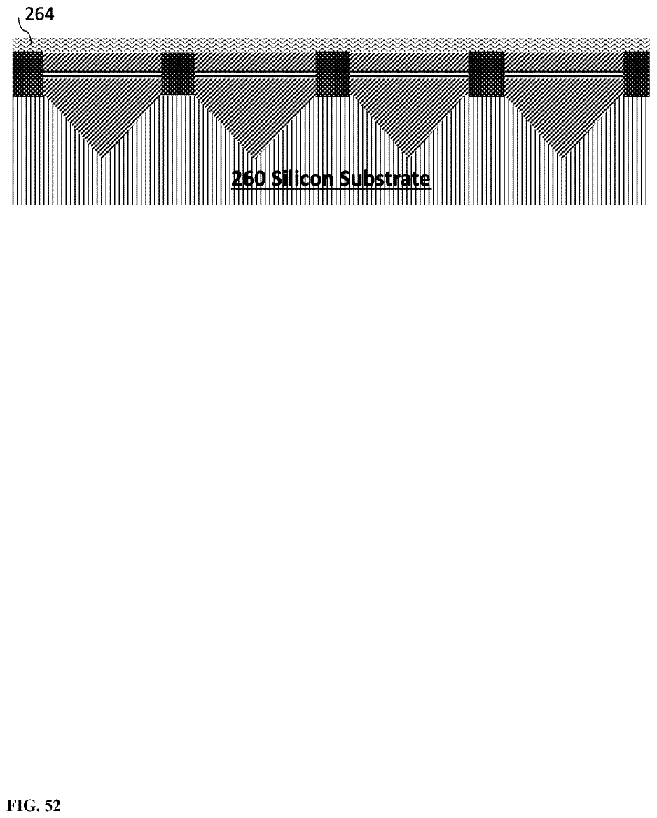

FIG. 51 illustrates a transparent conductive layer 264 deposited on top of the epitaxial layer. Material 264 may be a transparent conductive oxide (TCO) such as aluminum-doped zinc oxide (AZO), or indium tin oxide (ITO) or it may be a multilayer of oxide and metal with spectral bandwidth selectivity.

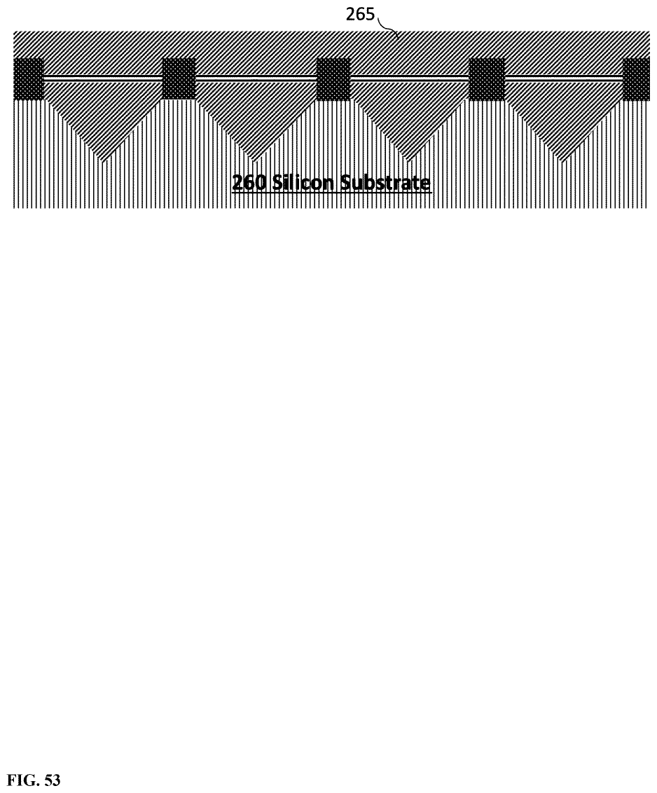

FIG. 52 illustrates an overgrown epitaxial layer 265 where the upper highly doped layer may be thicker than the dielectric layer. The overgrown epitaxial layer may coalesce at the top area and provide a common p-region that may be used for current spreading.

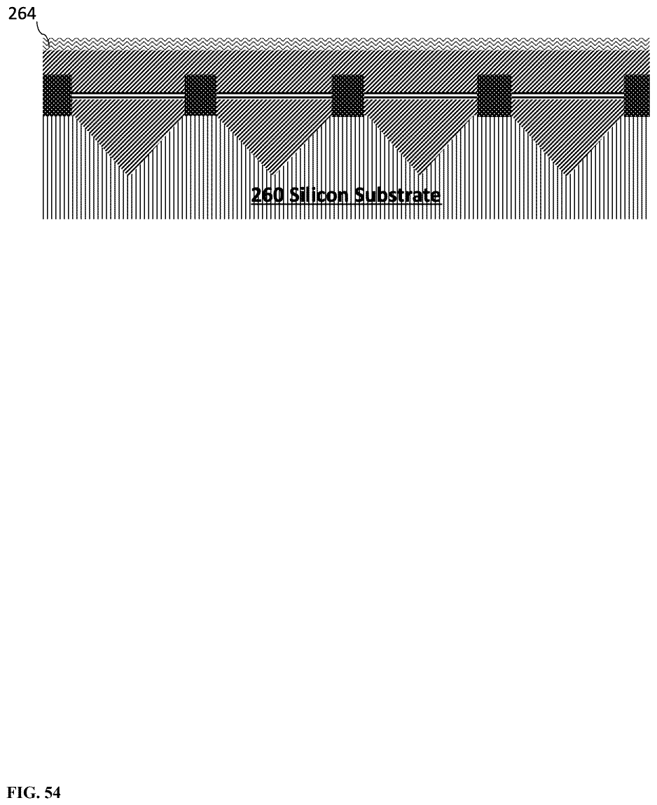

FIG. 53 illustrates a transparent ohmic contact 264 such as TCO which may be used to create ohmic contact to the p-region and as a current spreading layer. Additional thermal annealing may be implemented to reduce the thermal conductivity and create an ohmic contact.

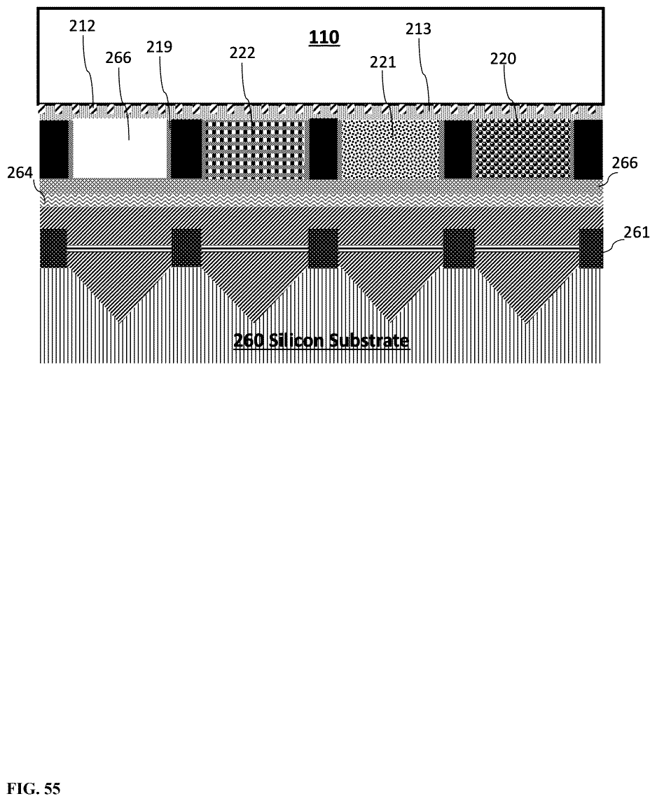

FIG. 54 illustrates the integration of the micro-LEDs with the optical substrate 110 having color-conversion and optical elements. Furthermore, the OCA may be used to bond the two structures together.

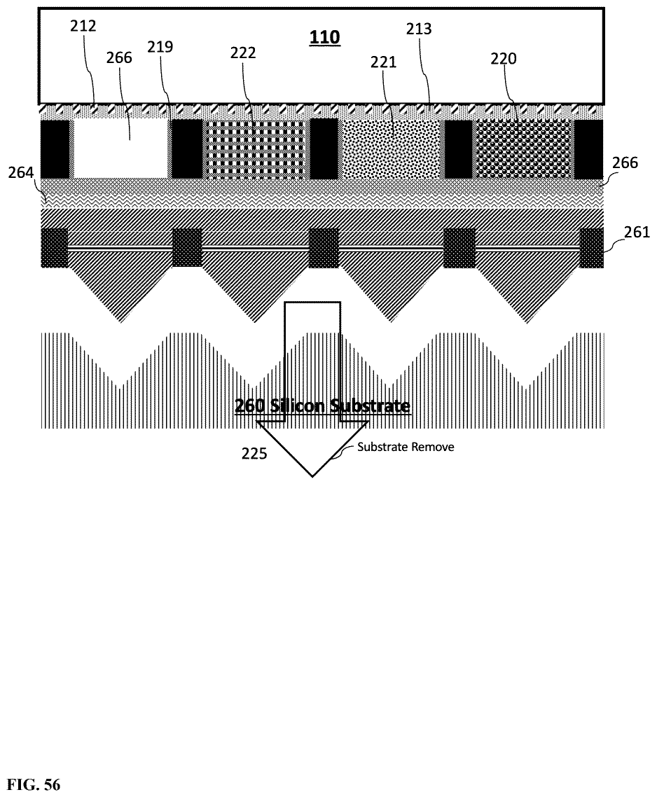

FIG. 55 illustrates the substrate removal process. As described before, the silicon substrate 260 may be removed by using grinding, polishing, and etching process. Additional wet or dry processing may be used to etch the micro-LEDs' backside to reduce the ohmic contact resistance.

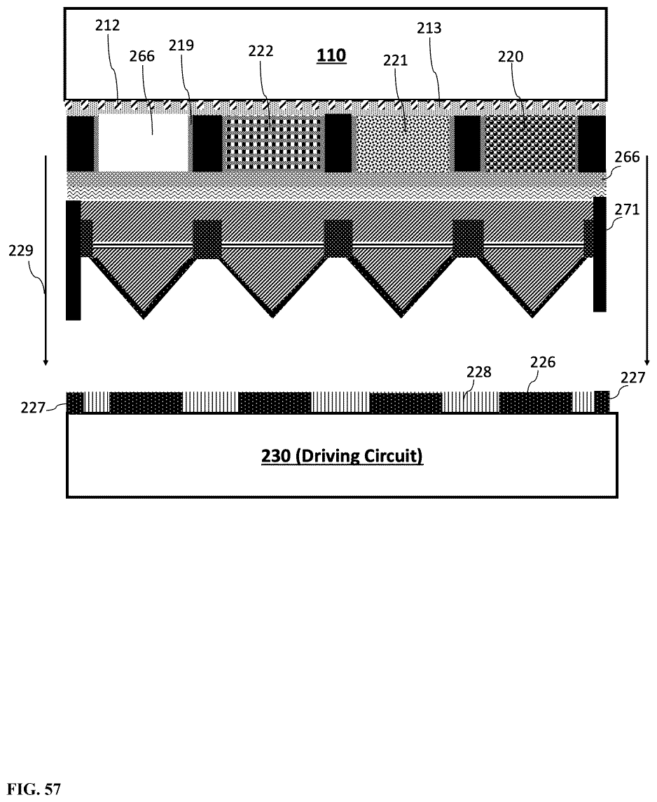

FIG. 56 illustrates the alignment process of micro-LEDs' back contact with bonding pads 226 and 227 on the driving circuit substrate 230. The backside of the micro-LEDs may be coated with a reflective low-ohmic metal 269 for providing contact with the driving circuit bonding pads and the LEDs.

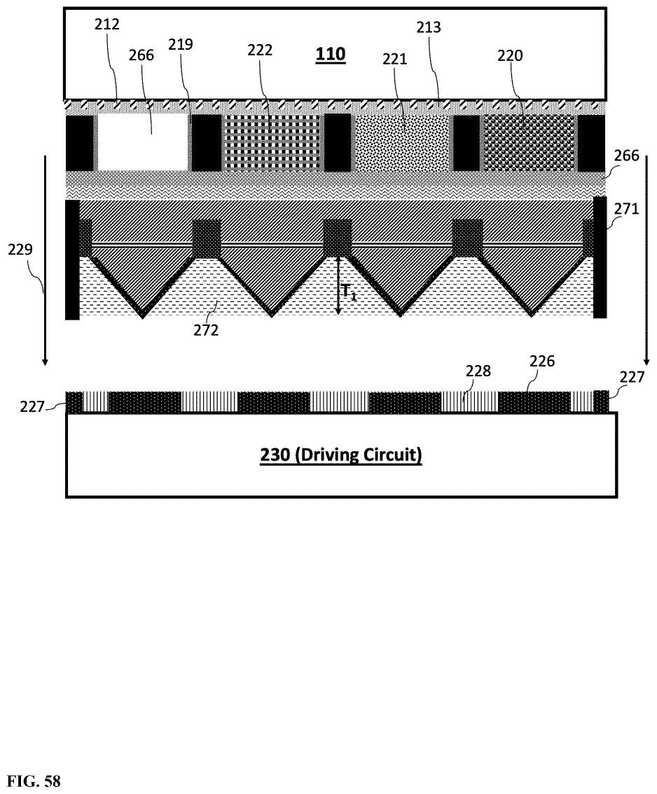

FIG. 57 illustrates the micro-LED structure when the space between them is filled with a polymer (or oxide) 272. This polymer 272 may help in the hybrid bonding and may provide additional mechanical strength after bonding to the 228 region. The thickness (T1) of the polymer layer may be designed when the backside tips of the micro-LEDs are exposed. To control the polymer 272 thickness, plasma ash, etching, or changing the coating parameters may be employed.

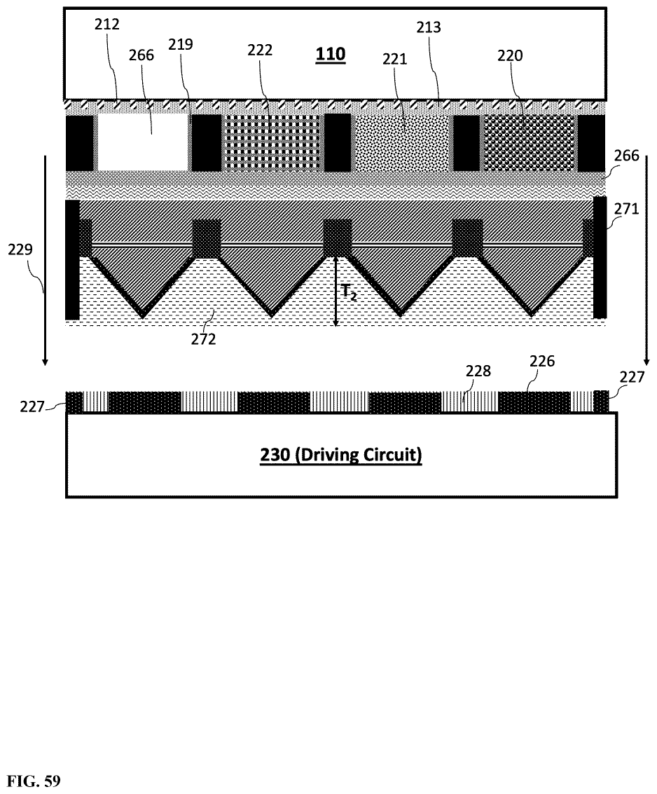

FIG. 58 illustrates the alignment process between the driving circuit substrate 230 and micro-LEDs' back contact when the polymer 272 may be thicker than the height of the micro-LEDs'. Since the micro-LEDs' backside is expected to be sharp, during the bonding process they may penetrate through the polymer and make electrical contact with the bonding pads on the driving circuit 230. The polymer thickness (T₂) may be tuned by spin coating or blade coating parameters. The polymer coating process may be performed with any other tools or processes.

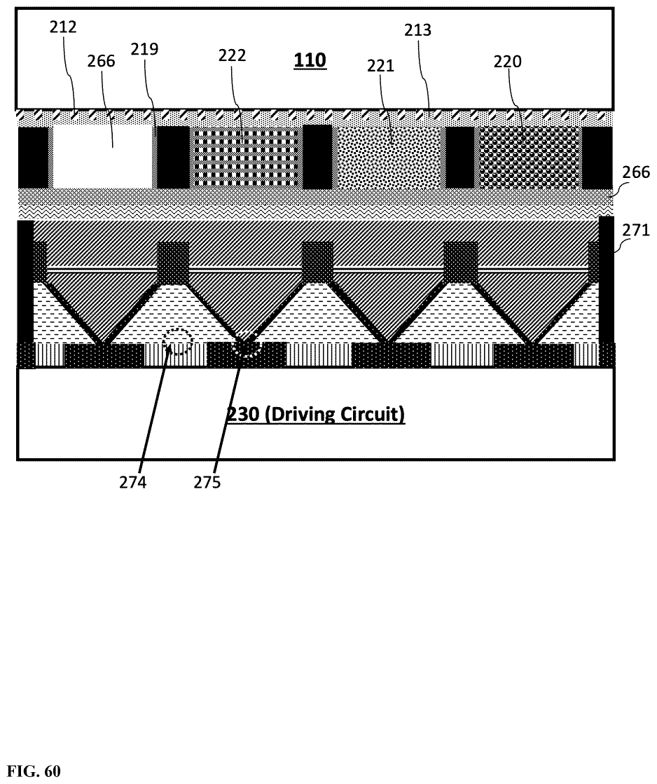

FIG. 59 illustrates a micro-LED display after the bonding process. The micro-LEDs' cathode may be penetrated or may be in electrical contact 275 with the bonding pads on the driving circuit substrate 230. The polymer may be in contact 274 with the spacer between the bonding pads to provide additional mechanical strength. The amount of penetration may be refined by controlling the bonding force, bonding temperature, and material properties of the bonding pads.

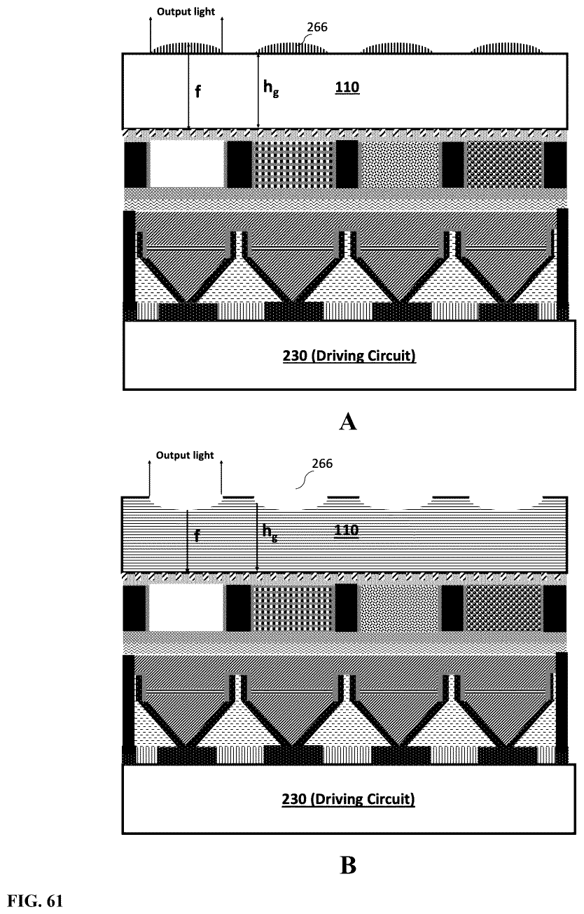

FIG. 60A illustrates a micro-LED display co-packaged with optical elements 266 such as micro-lenses. The curvature of the micro-lens and the optical substrate 110 thickness (h_{g}) may be designed in a way to position the focal height (f) (or focal point) on the other side of the optical substrate where optical elements (or homogenizers) have been created. The micro-LEDs' shape is not limited to what is presented herein and may be made in any other shape such as circular or rectangular. The micro-LED pixels may also be created with top-down etching process. The same optical structure may be applicable for all micro-LED structures. FIG. 60B illustrates a micro-LED display co-packaged with optical elements 266 which might be recessed from the surface.

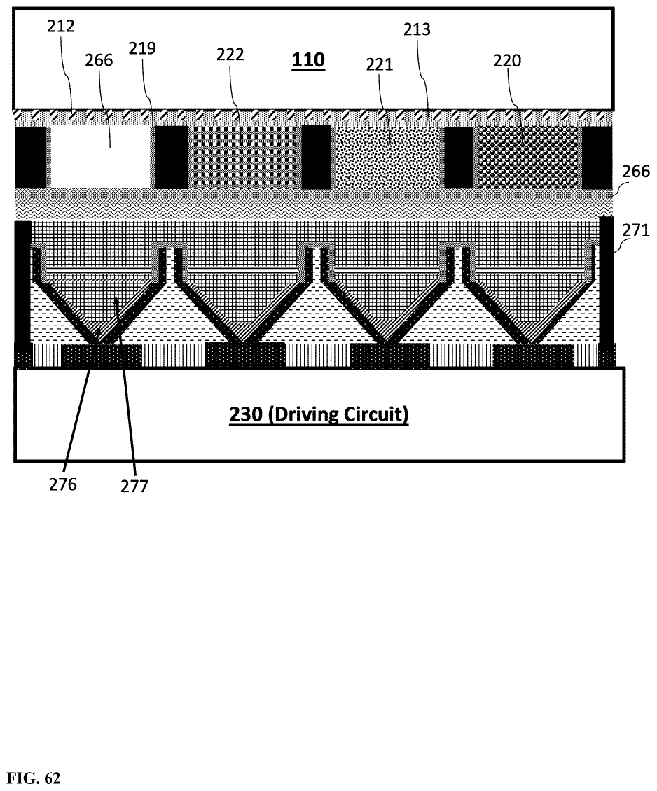

FIG. 61 illustrates a micro-LED structure where the epitaxial structure is made from two or more crystal phases 276 and 277. The bottom crystal phase (orientation) 276 may be different from the top crystal phase (orientation) 277 due to interfacing with silicon and possible coalescence of the crystal planes. If the internal sidewalls are coated partially with and oxide layer, the epitaxial growth phase change may be negligible or be controlled in the bottom of the groove. However, the phase transition structure and shape are not limited to grow epitaxial layer on [111] silicon crystal planes, and other crystal planes may be used to control the epitaxial layer phase and crystal properties.

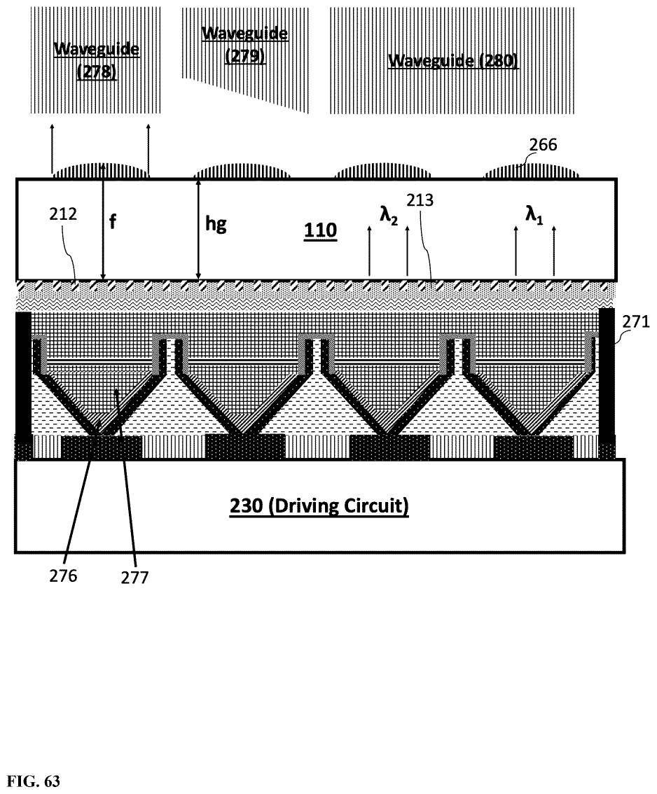

FIG. 62 illustrates a micro-LED display co-packaged with optical elements to couple the light into an external waveguide 278, 279 or 280. Depending on the waveguide size and shape, the optical elements and micro-lenses may be designed accordingly to achieve the maximum coupling and minimum insertion loss and a desired focal height (f). Also, the micro-LEDs may emit multiple wavelengths (if the active region may be possibly made from quantum dots) or neighbor micro-LEDs emit different wavelengths (λ₁) (λ₂). For example, RGB colors may be transmitted from three different micro-LEDs into different waveguides or into the same waveguide. The optical elements such as micro-lenses 266 then may be designed to guide each wavelength effectively, and different optical element shapes and parameters may be used. The optical elements 212 may be used to provide nearly constant optical intensity over each micro-LED and reduce the intensity outside of that area.

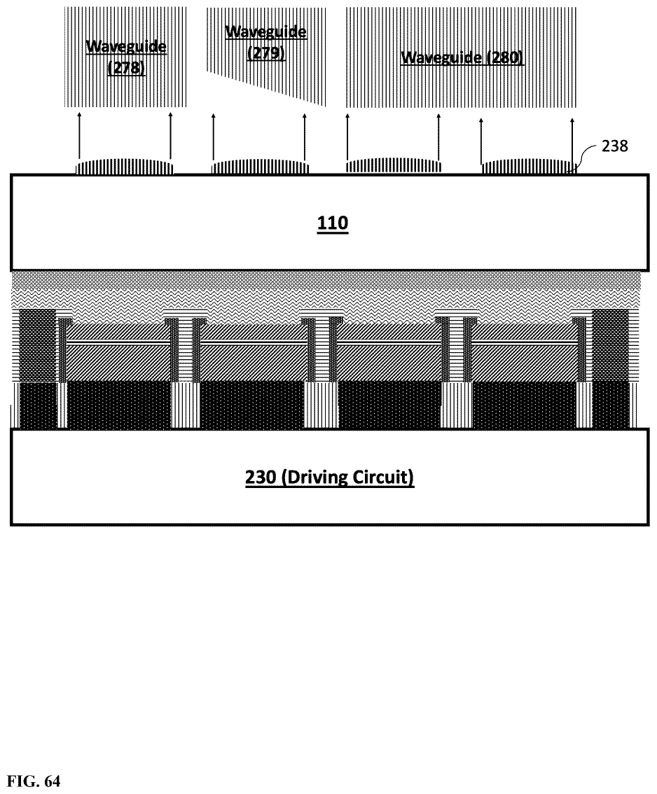

FIG. 63 illustrates a micro-LED display co-packaged with optics. Micro-LEDs may be made by any of the processes described herein. The optical substrate 110 may be bonded to the micro-LED display after micro-LED integration to the driving substrate (Optic-Last), or the optical substrate may be integrated on micro-LEDs on micro-device substrate and then both micro-LEDs and optics are assembled onto the driving circuit (Optic-First). Optical clear adhesive (OCA) 266 may also be used to attach the optical substrate to the micro-LEDs and possibly to enhance the light extraction efficiency.

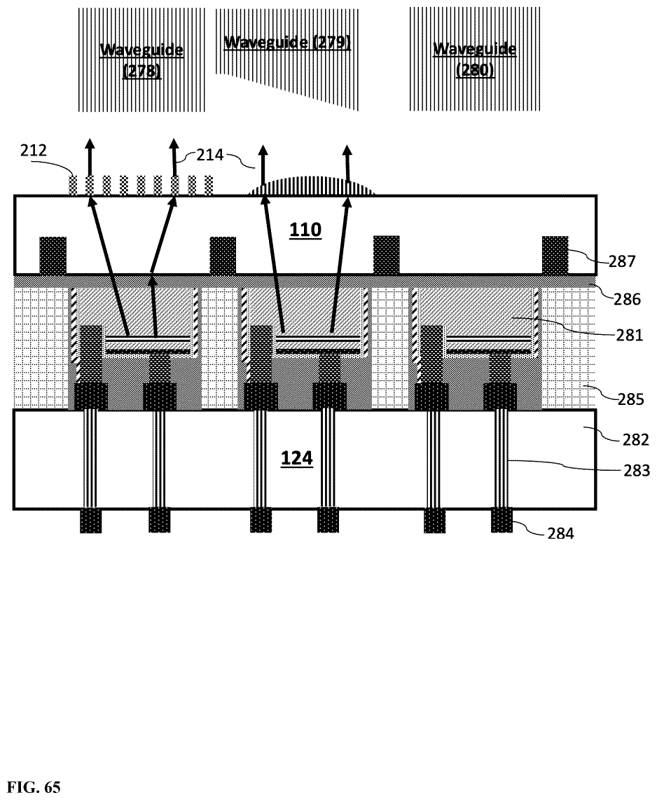

FIG. 64 illustrates flip-chip (FC) micro-LEDs 281 co-packaged with optics. Micro-LEDs 281 are integrated onto a receiver substrate 282 and are connected to the other side of substrate 282 using through substrate vias (TSV) 283. The bonding pads 284 on the other side of the substrate may be used to test the functionality of the micro-LEDs 281 or may be used to connect micro-LEDs to a driving circuit. The space between micro-LEDs may be filled with a material 285 to provide mechanical strength for the package and for better thermal conductivity and possibly surface planarization. An OCA 286 may be used to assemble the optical substrate 110 to the micro-LED structure. Optical substate 110 may have structure 287 to guide or block the photons and reduce the pixels' crosstalk. There may be different types of optical elements 212 or 266 that may be used to enhance the light coupling from the micro-LEDs into the waveguides 278 and 279 and 280. All the optical elements may be fabricated using thin-film or bulk processing on the optical substrate 110 before being assembled into the micro-LEDs. Fiducial structure and alignment process may be used to bond the right optics onto a specific micro-LED.

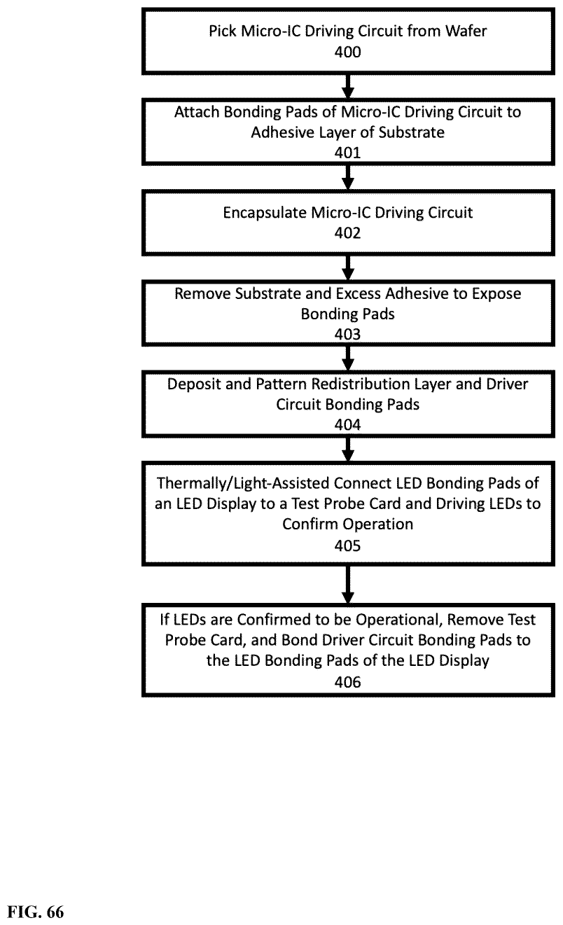

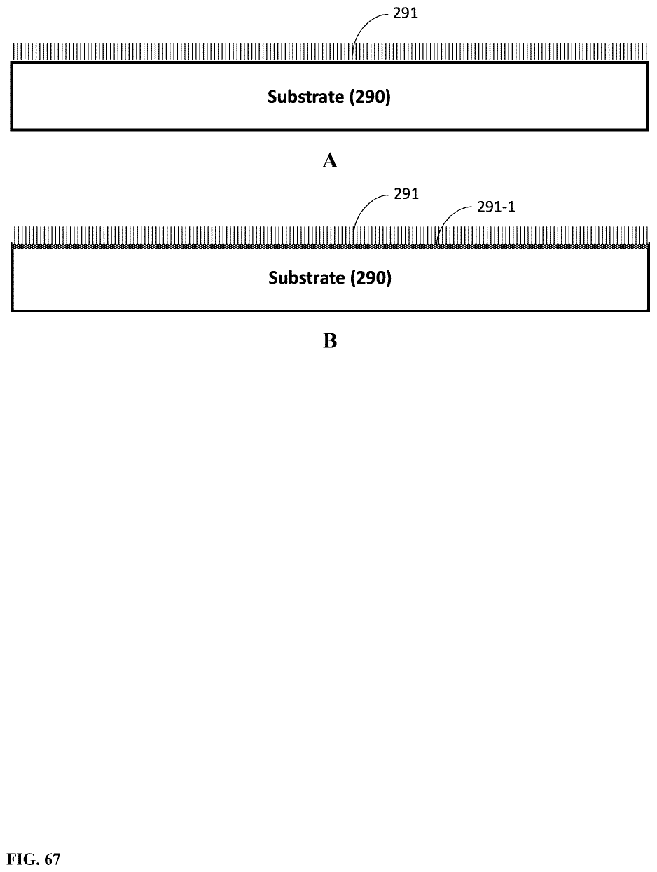

FIG. 65 illustrates the overall fabrication process of combining a micro-LED display with driver circuitry. Specifically, in step 400, the fabricated micro-IC driving circuits are picked from a wafer, and their body and bonding pads are attached to an adhesive layer of a substrate in step 401. In step 402, the micro-IC driving circuits are encapsulated for protection, and in step 403, the excess adhesive is removed to expose the micro-IC driving circuit bonding pads. Then in step 404, the RDL layers and additional bonding pads are deposited. In step 405, prior to bonding the LED display to the micro-IC driving circuits, the LEDs are tested by temporarily connecting the LED display bonding pads to a probe card for testing. Once the electrical and optical operations of the LEDs are verified, the bonding pads of the LED display are bonded to the bonding pads of the micro-IC driving circuits to complete the micro-LED display. The steps described in FIG. 65 will now be described in further detail with respect to FIGS. 66-80 below.

FIG. 66A illustrates a carrier substrate 290 with an adhesive layer 291 thereon. This substrate may be temporarily used for a few processes and then released. The adhesive layer 291 may be deposited using spin or blade coating.

FIG. 66B illustrates a carrier substrate with a sacrificial layer 291-1 and an adhesive layer 291 thereon. The sacrificial layer may be used to delaminate the adhesive layer 291 from the carrier substrate using laser liftoff, chemical lift-off or physical lift-off.

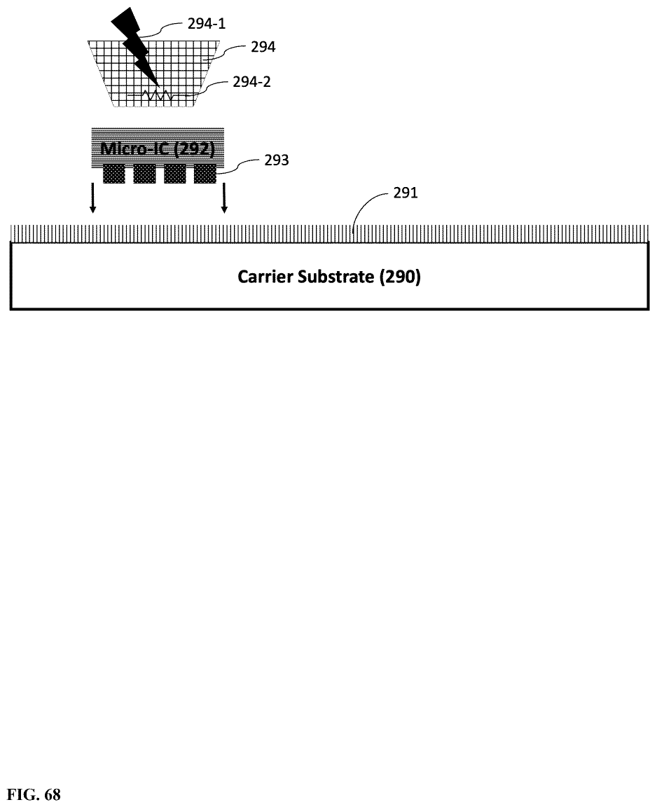

FIG. 67 illustrates a flip chip assembly of a micro-IC onto the adhesive layer. The micro-IC may be picked from a wafer and attached to the substrate face down. The electrode 293 may be made from copper capped with other metals like gold or nickel. A pick-and-place head 294 may pick the micro-IC from a wafer or holder and bond it to the adhesive layer 291. A local light source like laser 294-1 or heat source 294-2 may be used to cure the adhesive layer locally and keep the remaining surface intact.

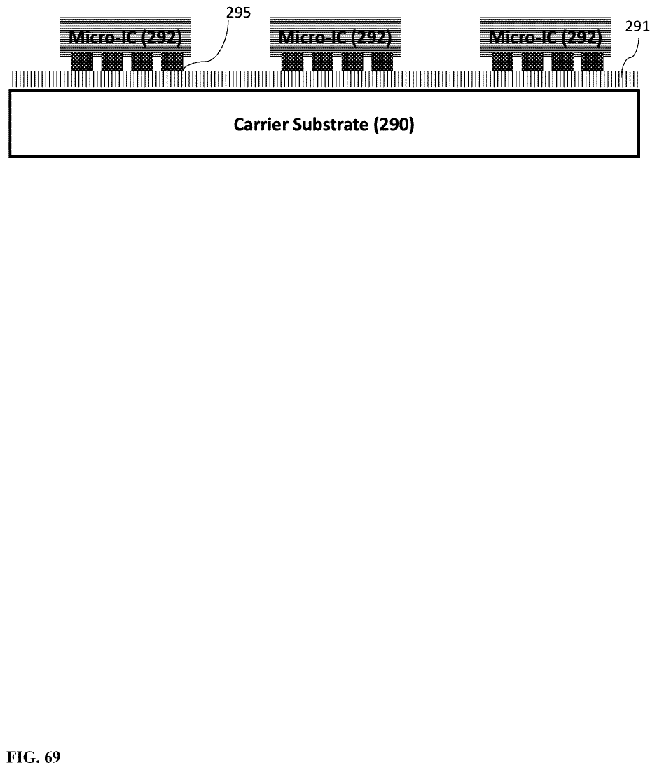

FIG. 68 illustrates the micro-ICs 292 after assembly on the carrier substrate 290. The micro-ICs are arranged based on fiducial marks on the carrier substrate or a self-assembly process. The micro-ICs' pad 293 may stay on top 295 of the adhesive layer 291.

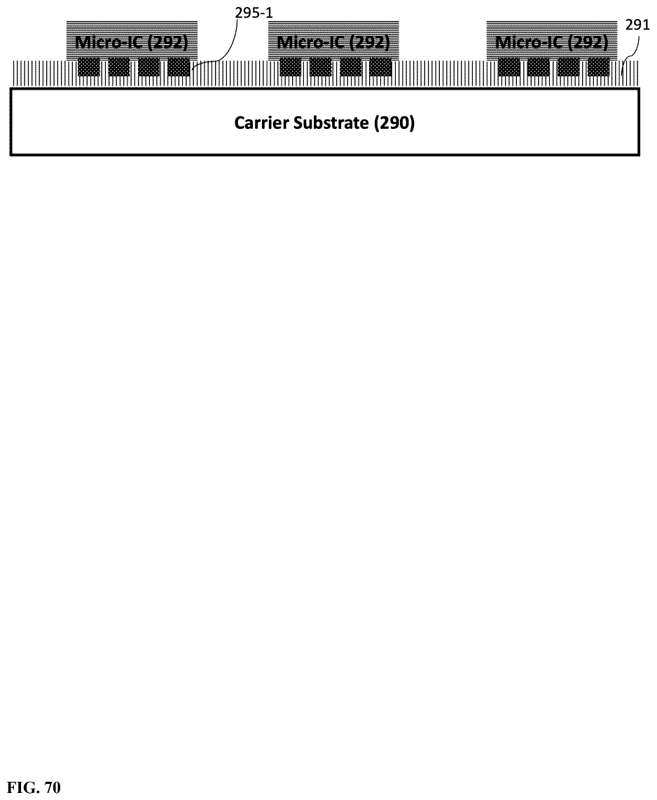

FIG. 69 illustrates micro-ICs 292 assembled on the carrier substrate 290. If enough force is applied by pick-and-place head 294, the micro-IC pads may penetrate 295-1 into the adhesive layer to a desired depth.

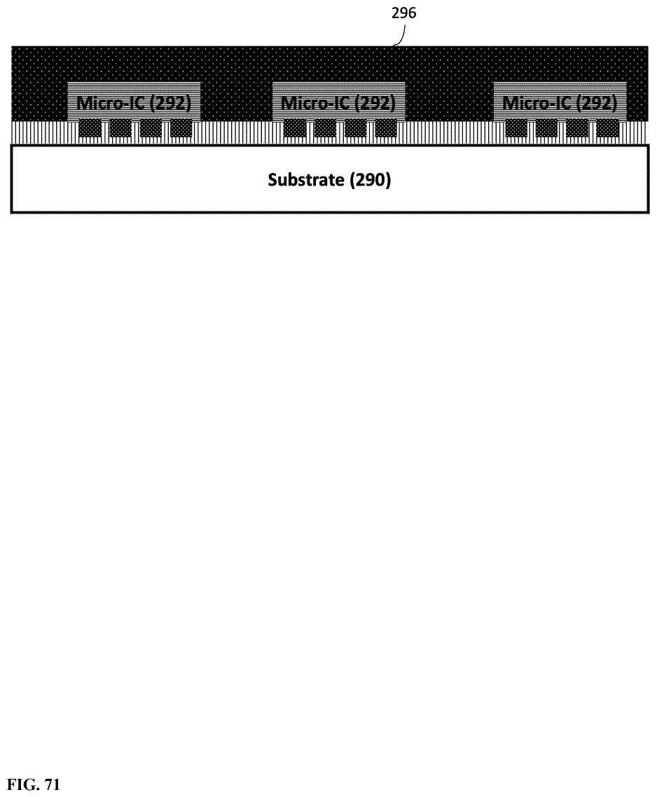

FIG. 70 illustrates a molding material 296 encapsulating the micro-ICs. The molding material may be a liquid at first and may be applied by blade coating or spin coating. The molding material 296 may be a low-temperature co-fired ceramic that may provide thermal conductivity. Additional steps such as thermal or laser curing may be used to cure the molding material and turn it into a solid material.

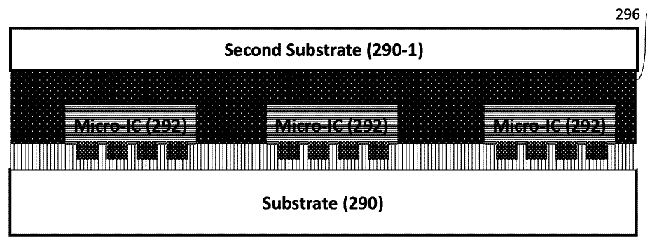

FIG. 71 illustrates the second substrate 290-1 attached to the molding material 296. An adhesive may be used to assemble surfaces together. If the molding material is flexible or if the mechanical strength is not enough for large-area processing, adding a second substrate 290-1 may help in handling the micro-ICs. The second substrate 290-1 may be removed later using lift-off processes to finalize the process and provide a flexible structure.

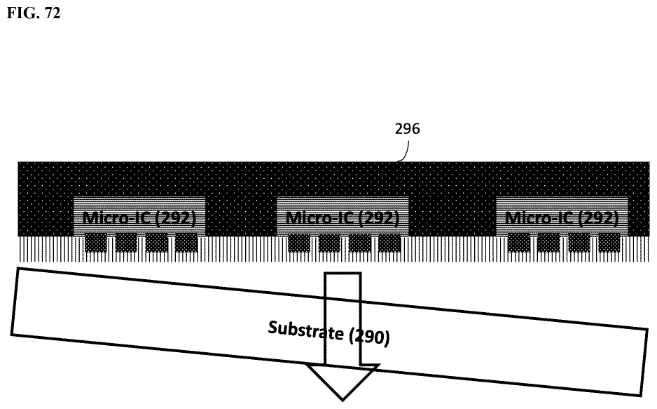

FIG. 72 illustrates the substrate removal process. Carrier substrate 290 which may be made from glass may be removed using a laser liftoff, chemical liftoff, or physical delamination. In this process, all the micro-ICs 292 are transferred onto the mold layer 296.

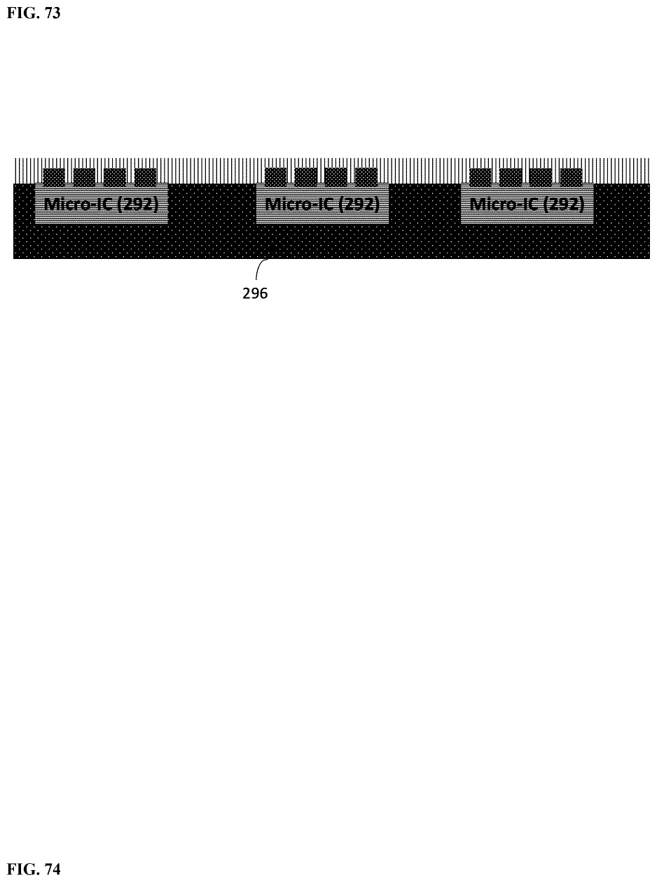

FIG. 73 shows the micro-ICs 292 embedded in a mold material 296 flipped upside after the carrier substrate removal process. The upper side of the structure is covered with an adhesive polymer layer.

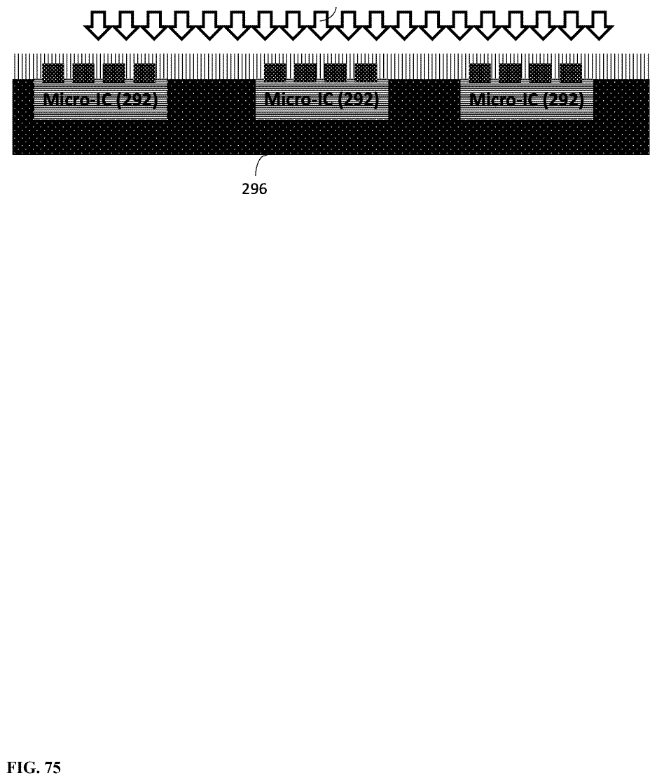

FIG. 74 illustrates the process step 297 to remove the excess adhesive polymer from top of the micro-ICs 292. The objective may be to expose the micro-IC pads and provide a planar surface for further thin-film processing.

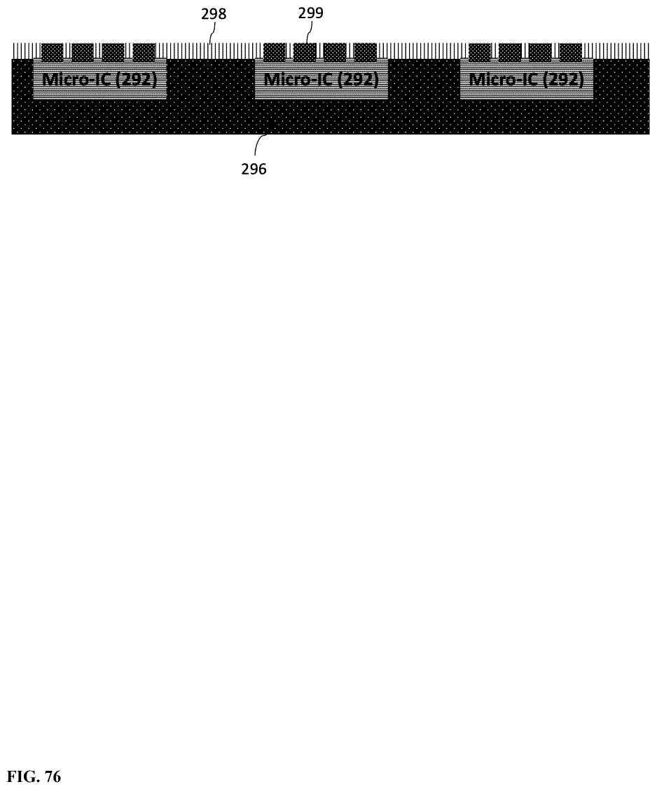

FIG. 75 illustrates the micro-ICs 292 with exposed electrodes 299. The electrodes 299 may have been fabricated on the micro-ICs 292 before transport or they may be fabricated after top surface exposure. The surface of the adhesive polymer may benefit from being flat for further thin-film processing thereon. A fine polishing process may be employed to reduce the electrodes' 229 and surface 298 roughness.

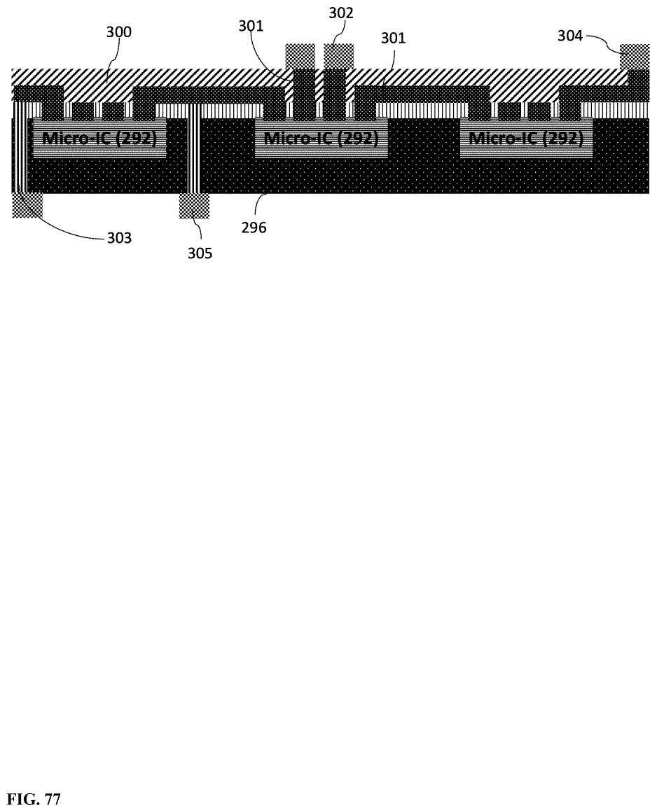

FIG. 76 illustrates the redistribution line (RDL) processing on the micro-ICs 292 and mold substrate 296. When the micro-ICs' electrode is exposed, thin-film processes such as dielectric 300 coating, metal coating, lithography and etching may be used to complete the redistribution metal lines 301. Depending on the functionality and active device on the next layer, several RDL layers may be created in this step. Micro-ICs 292 may be in contact with micro-devices (micro-LEDs or sensors) using via-shape 301 metal lines. In order to prepare the surface for integration into the next devices (such as micro-LEDs or sensors) bonding pads 302 may be created on the surface. In order to connect the micro-ICs 292 to the data and power sources, pads 304 on the surface or through substrate (mold) vias 303 may be used. Pads 305 on the backside of the substrate may be created for electrical contact. If voltage signals such as V_{dd} or Vₛₛ signals are shared between micro-ICs, all of them may be arranged in a parallel manner and may be connected to a direct line on the surface.

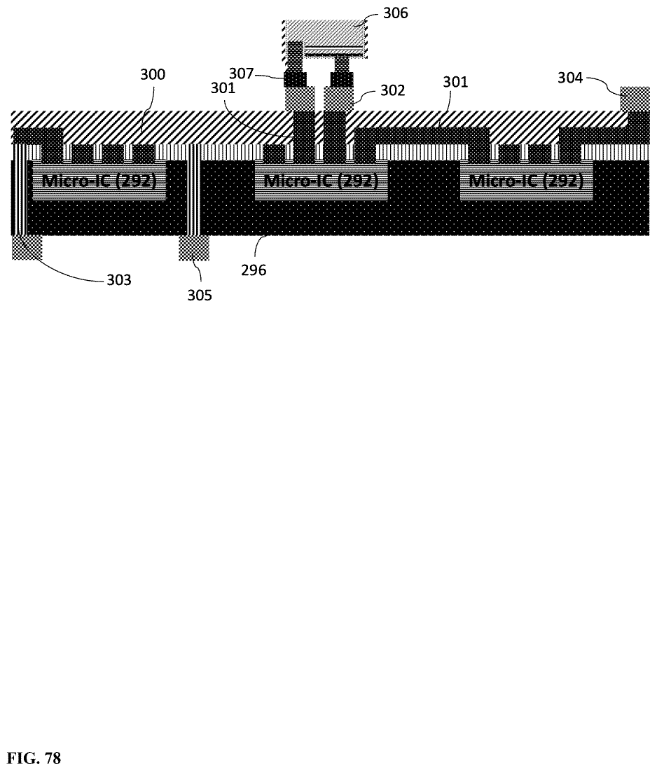

FIG. 77 illustrates a micro-LED 306 assembled onto the bonding pads 302 on the substrate with micro-ICs 292. Micro-LEDs may be transferred directly from a growth substrate or from an intermediate (carrier) substrate. Micro-LED's bonding pad 307 may be assembled onto the 302 pads using solder joint, thermo-compression, hybrid bonding or any other possible technique.

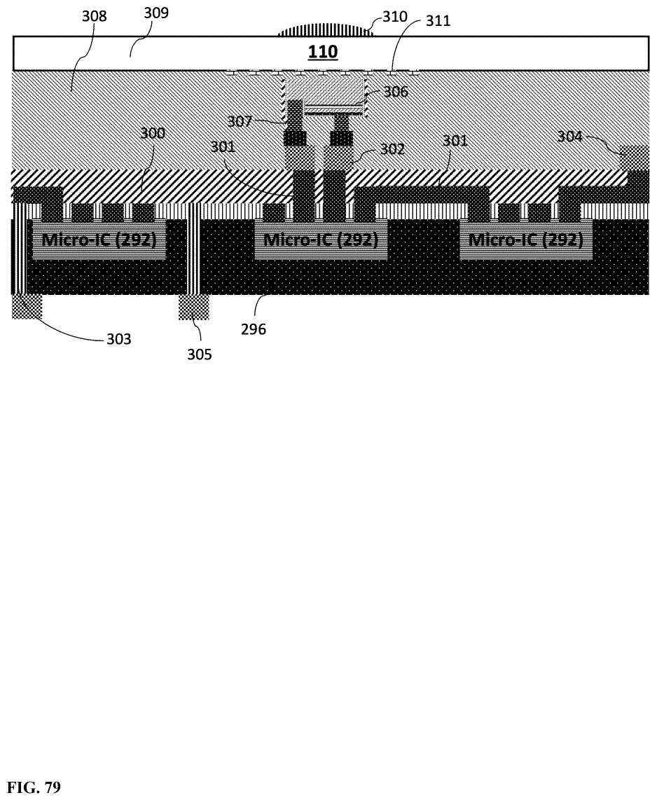

FIG. 78 illustrates a micro-LED display co-packaged with optics. An optical clear adhesive 308 may be used to assemble an optical clear substrate 309 onto the package. Optical elements 310 and 311 may be created on both sides of the optical clear substrate 309 before integration or after integration. Optical elements 311 and 312 may be meta-lenses, diffractive optic elements, micro-lens or any other optical structure made using thin-film and bulk processing. Optical elements guide the light and help further light extraction or polarization control of the output light.

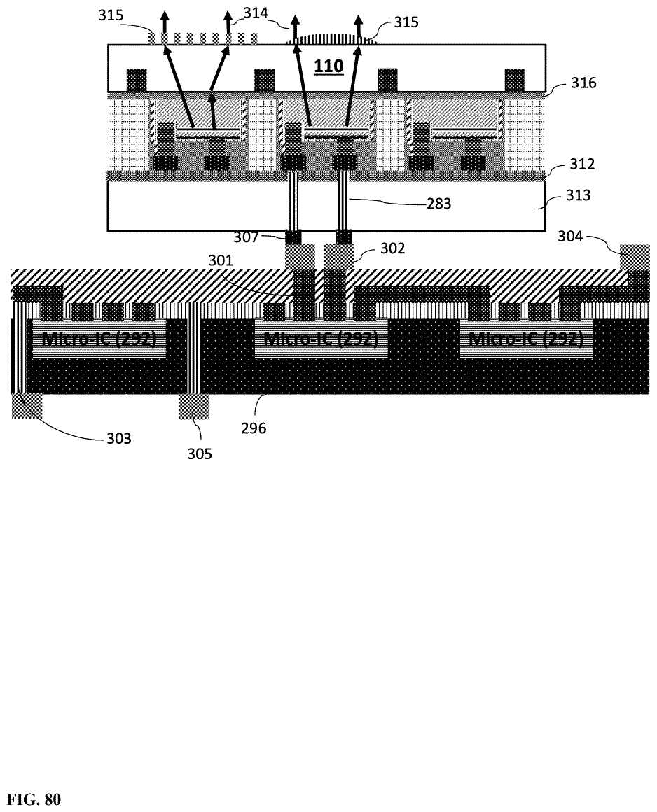

FIG. 79 illustrates a micro-LED display co-packaged with optics. Micro-LEDs may be initially transferred and assembled onto a substrate 313. RDLs 312 may be created on substrate 313 to distribute the power and data between micro-LEDs. An optical substrate 110 with optical elements 315 (such as micro-lens, meta lens, homogenizer, polarizer) thereon may be integrated to the micro-LEDs using optical clear adhesives 316. Micro-LEDs and RDLs are connected to the micro-ICs 292 by through substrate vias 283. As an advantage of this technology micro-LED structure with their optics may be functionally tested before assembling to the micro-IC substrate.

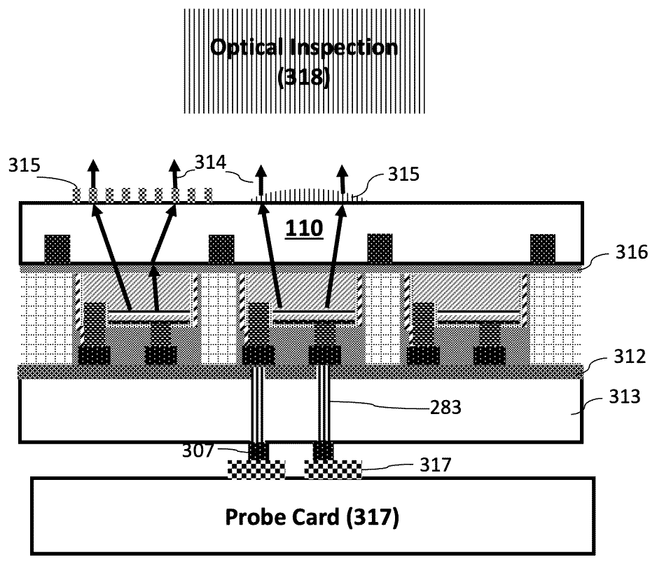

FIG. 80 illustrates a test procedure of the micro-LEDs co-packaged with optics before integrating onto micro-IC substrate. A probe card 317 that may implement a MEMS probe to drive the micro-LEDs electrically to measure the electrical characteristics such as IV, CV, or any other possible electrical data. In addition, an optical inspection head may measure the optoelectrical properties of the micro-LEDs such as electroluminescence (EL), external quantum efficiency (EQE), angular emission and uniformity. This test strategy may sort the high-performance micro-LED structures and improved the final product yield by integrating qualified micro-LED onto micro-IC substrate. It is noted that the micro-ICs described herein could include a processor, memory and/or other devices for driving the micro-LEDs.

In an example, the disclosure herein provides a display including light emitting diodes (LEDs) fabricated on an LED wafer, light reflecting sidewalls coating side surfaces of each of the LEDs, and LED bonding pads fabricated on the LED wafer, the LED bonding pads being electrically connected to the LEDs, a color conversion optical wafer bonded to the LED wafer to covert light emitted from the LEDs, a light manipulating optical wafer bonded to the color conversion optical wafer to manipulate the converted light emitted from the color conversion optical wafer, and LED driver circuits including driver circuit bonding pads bonded to the LED bonding pads to electrically connect the LED driver circuits to the LEDs.

In an example, the light manipulating optical wafer includes passive optics for manipulating the light emitted from the color conversion optical wafer. In an example, the light manipulating optical wafer includes voltage controlled active optics for manipulating the light emitted from the color conversion optical wafer. In an example, the light manipulation includes at least one of light collection, light collimation and light focusing of the converted light emitted from the color conversion optical wafer. In an example, the display includes a black matrices separating distinct color conversion sections of the color conversion optical wafer. In an example, the display is integrated into an augmented reality headset or a virtual reality headset. In an example, the side surfaces of the LEDs include a sloped region coated by the light reflecting sidewalls, the sloped region coming to a point that pierces the driver circuit bonding pads such that the driver circuit bonding pads are electrically connected to the LEDs.

In an example, the disclosure herein also provides a method of manufacturing a display. The method includes fabricating light emitting diodes (LEDs) on an LED wafer, fabricating light reflecting sidewalls coating side surfaces of each of the LEDs, fabricating LED bonding pads on the LED wafer, the LED bonding pads being electrically connected to the LEDs, fabricating a color conversion optical wafer bonded to the LED wafer to covert light emitted from the LEDs, fabricating a light manipulating optical wafer bonded to the color conversion optical wafer to manipulate the converted light emitted from the color conversion optical wafer, temporarily connecting the LED bonding pads to a test circuit and confirming operation of the LEDs, removing the LED bonding pads from the test circuit when operation of the LEDs are confirmed, and aligning and electrically connecting the LED bonding pads to driver bonding pads of LED driver circuits to electrically connect the LED driver circuits to the LEDs.

In an example, the method includes fabricating passive optics on the light manipulating optical wafer for manipulating the light emitted from the color conversion optical wafer. In an example, the method includes fabricating voltage controlled active optics on the light manipulating optical wafer for manipulating the light emitted from the color conversion optical wafer. In an example, the method includes fabricating the light manipulating optical wafer to perform at least one of light collection, light collimation and light focusing of the converted light emitted from the color conversion optical wafer. In an example, the method includes fabricating black matrices on the color conversion optical wafer for separating distinct color conversion sections of the color conversion optical wafer. In an example, the method includes integrating the display into an augmented reality headset or a virtual reality headset. In an example, the method includes fabricating the side surfaces of the LEDs to include a sloped region coated by the light reflecting sidewalls, such that the sloped region comes to a point, and forcing the points of the LEDs to pierce the driver circuit bonding pads such that the LED bonding pads are electrically connected to the LEDs.

In an example, the disclosure herein also provides a display including light emitting diodes (LEDs) fabricated on an LED wafer, light reflecting sidewalls coating side surfaces of each of the LEDs, and LED bonding pads fabricated on the LED wafer, the LED bonding pads being electrically connected to the LEDs, an color conversion optical wafer bonded to the LED wafer to covert light emitted from the LEDs, and a light manipulating optical wafer bonded to the color conversion optical wafer to manipulate the converted light emitted from the color conversion optical wafer. In an example, the light manipulating optical wafer includes passive optics for manipulating the light emitted from the color conversion optical wafer. In an example, the light manipulating optical wafer includes voltage controlled active optics for manipulating the light emitted from the color conversion optical wafer. In an example, the light manipulation includes at least one of light collection, light collimation and light focusing of the converted light emitted from the color conversion optical wafer. In an example, the display includes black matrices separating distinct color conversion sections of the color conversion optical wafer. In an example, the side surfaces of the LEDs include a sloped region coated by the light reflecting sidewalls, the sloped region coming to a point.

In an example, the disclosure herein also provides a method of manufacturing a display. The method includes fabricating light emitting diodes (LEDs) on an LED wafer, fabricating light reflecting sidewalls coating side surfaces of each of the LEDs, fabricating LED bonding pads on the LED wafer, the LED bonding pads being electrically connected to the LEDs, fabricating a color conversion optical wafer bonded to the LED wafer to covert light emitted from the LEDs, and fabricating a light manipulating optical wafer bonded to the color conversion optical wafer to manipulate the converted light emitted from the color conversion optical wafer.

In an example, the method includes fabricating passive optics on the light manipulating optical wafer for manipulating the light emitted from the color conversion optical wafer. In an example, the method includes fabricating voltage controlled active optics on the light manipulating optical wafer for manipulating the light emitted from the color conversion optical wafer. In an example, the method includes fabricating the light manipulating optical wafer to perform at least one of light collection, light collimation and light focusing of the converted light emitted from the color conversion optical wafer. In an example, the method includes fabricating black matrices on the color conversion optical wafer for separating distinct color conversion sections of the color conversion optical wafer. In an example, the method includes fabricating the side surfaces of the LEDs to include a sloped region coated by the light reflecting sidewalls, such that the sloped region comes to a point.

A benefit to the micro-LED display described herein is the co-packaging of the LEDs and the supporting optics into a common package that is both thin and lightweight. The final co-packaged product can then be integrated into various systems to support optical data transmission between transmitters and receivers, and/or to visually display information to users. Example use cases for the micro-LED display described herein include but are not limited to fiber optic transmission and AR/VR displays.

In one example, the micro-LED display may transmit optical signals from the LEDs at one or more wavelengths which are optically manipulated (e.g. homogenized, collimated, etc.) in a manner that ensures efficient transmission to an external waveguide (fiber optic cable). A transmitter may control the micro-LED display to transmit light to represent digital data that is to be transmitted over the waveguide to an optical receiver.

In another example, the micro-LED display may be implemented in AR/VR displays such as headsets, goggles, glasses among others. Due to the thin structure of the micro-LED display, the user experience is enhanced. In addition, when active optics are integrated into the micro-LED display, the display is able to adjust to the user's vision capabilities, thereby providing an experience that is tailored to a specific user. These adjustments may be performed automatically based on feedback from the user's eyes (e.g. pupils) or manually by the user providing feedback to the device via buttons and other users I/Os.

While the foregoing is directed to example embodiments described herein, other and further example embodiments may be devised without departing from the basic scope thereof. For example, aspects of the present disclosure may be implemented in hardware or software or a combination of hardware and software. One example embodiment described herein may be implemented as a program product for use with a computer system. The program(s) of the program product define functions of the example embodiments (including the methods described herein) and can be contained on a variety of computer-readable storage media. Illustrative computer-readable storage media include, but are not limited to: (i) non-writable storage media (e.g., read-only memory (ROM) devices within a computer, such as CD-ROM disks readably by a CD-ROM drive, flash memory, ROM chips, or any type of solid-state non-volatile memory) on which information is permanently stored; and (ii) writable storage media (e.g., floppy disks within a diskette drive or hard-disk drive or any type of solid state random-access memory) on which alterable information is stored. Such computer-readable storage media, when carrying computer-readable instructions that direct the functions of the disclosed example embodiments, are example embodiments of the present disclosure.

It will be appreciated to those skilled in the art that the preceding examples are exemplary and not limiting. It is intended that all permutations, enhancements, equivalents, and improvements thereto are apparent to those skilled in the art upon a reading of the specification and a study of the drawings are included within the true spirit and scope of the present disclosure. It is therefore intended that the following appended claims include all such modifications, permutations, and equivalents as fall within the true spirit and scope of these teachings.

What is claimed is:

1. A display comprising:
light emitting diodes (LEDs) fabricated on an LED wafer, light reflecting sidewalls coating side surfaces of each of the LEDs, and LED bonding pads fabricated on the LED wafer, the LED bonding pads being electrically connected to the LEDs;
an color conversion optical wafer bonded to the LED wafer to covert light emitted from the LEDs;
a light manipulating optical wafer bonded to the color conversion optical wafer to manipulate the converted light emitted from the color conversion optical wafer; and
LED driver circuits including driver circuit bonding pads bonded to the LED bonding pads to electrically connect the LED driver circuits to the LEDs.

2. The display of claim 1, wherein the light manipulating optical wafer includes passive optics for manipulating the light emitted from the color conversion optical wafer.

3. The display of claim 1, wherein the light manipulating optical wafer includes voltage controlled active optics for manipulating the light emitted from the color conversion optical wafer.

4. The display of claim 1, wherein the light manipulation includes at least one of light collection, light collimation and light focusing of the converted light emitted from the color conversion optical wafer.

5. The display of claim 1, further comprising black matrices separating distinct color conversion sections of the color conversion optical wafer.

6. The display of claim 1, wherein the display is integrated into an augmented reality headset or a virtual reality headset.

7. The display of claim 1, wherein the side surfaces of the LEDs include a sloped region coated by the light reflecting sidewalls, the sloped region coming to a point that pierces the driver circuit bonding pads such that the driver circuit bonding pads are electrically connected to the LEDs.

8. A method of manufacturing a display, the method comprising:
fabricating light emitting diodes (LEDs) on an LED wafer;
fabricating light reflecting sidewalls coating side surfaces of each of the LEDs;
fabricating LED bonding pads on the LED wafer, the LED bonding pads being electrically connected to the LEDs;
fabricating a color conversion optical wafer bonded to the LED wafer to covert light emitted from the LEDs;
fabricating a light manipulating optical wafer bonded to the color conversion optical wafer to manipulate the converted light emitted from the color conversion optical wafer;
temporarily connecting the LED bonding pads to a test circuit and confirming operation of the LEDs;
removing the LED bonding pads from the test circuit when operation of the LEDs are confirmed; and
aligning and electrically connecting the LED bonding pads to driver bonding pads of LED driver circuits to electrically connect the LED driver circuits to the LEDs.

9. The method of manufacturing a display of claim 8, further comprising:
fabricating passive optics on the light manipulating optical wafer for manipulating the light emitted from the color conversion optical wafer.

10. The method of manufacturing a display of claim 8, further comprising:
fabricating voltage controlled active optics on the light manipulating optical wafer for manipulating the light emitted from the color conversion optical wafer.

11. The method of manufacturing a display of claim 8, further comprising:
fabricating the light manipulating optical wafer to perform at least one of light collection, light collimation and light focusing of the converted light emitted from the color conversion optical wafer.

12. The method of manufacturing a display of claim 8, further comprising:
fabricating black matrices on the color conversion optical wafer for separating distinct color conversion sections of the color conversion optical wafer.

13. The method of manufacturing a display of claim 8, further comprising:
integrating the display into an augmented reality headset or a virtual reality headset.

14. The method of manufacturing a display of claim 8, further comprising:
fabricating the side surfaces of the LEDs to include a sloped region coated by the light reflecting sidewalls, such that the sloped region comes to a point; and
forcing the points of the LEDs to pierce the driver circuit bonding pads such that the LED bonding pads are electrically connected to the LEDs.

15. A display comprising:
light emitting diodes (LEDs) fabricated on an LED wafer, light reflecting sidewalls coating side surfaces of each of the LEDs, and LED bonding pads fabricated on the LED wafer, the LED bonding pads being electrically connected to the LEDs;
an color conversion optical wafer bonded to the LED wafer to covert light emitted from the LEDs; and
a light manipulating optical wafer bonded to the color conversion optical wafer to manipulate the converted light emitted from the color conversion optical wafer.

16. The display of claim 15, wherein the light manipulating optical wafer includes passive optics for manipulating the light emitted from the color conversion optical wafer.

17. The display of claim 15, wherein the light manipulating optical wafer includes voltage controlled active optics for manipulating the light emitted from the color conversion optical wafer.

18. The display of claim 15, wherein the light manipulation includes at least one of light collection, light collimation and light focusing of the converted light emitted from the color conversion optical wafer.

19. The display of claim 15, further comprising black matrices separating distinct color conversion sections of the color conversion optical wafer.

20. The display of claim 15, wherein the side surfaces of the LEDs include a sloped region coated by the light reflecting sidewalls, the sloped region coming to a point.

21. A method of manufacturing a display, the method comprising:
fabricating light emitting diodes (LEDs) on an LED wafer;
fabricating light reflecting sidewalls coating side surfaces of each of the LEDs;
fabricating LED bonding pads on the LED wafer, the LED bonding pads being electrically connected to the LEDs;
fabricating a color conversion optical wafer bonded to the LED wafer to covert light emitted from the LEDs; and
fabricating a light manipulating optical wafer bonded to the color conversion optical wafer to manipulate the converted light emitted from the color conversion optical wafer.

22. The method of manufacturing a display of claim 21, further comprising:
fabricating passive optics on the light manipulating optical wafer for manipulating the light emitted from the color conversion optical wafer.

23. The method of manufacturing a display of claim 21, further comprising:
fabricating voltage controlled active optics on the light manipulating optical wafer for manipulating the light emitted from the color conversion optical wafer.

24. The method of manufacturing a display of claim 21, further comprising:
fabricating the light manipulating optical wafer to perform at least one of light collection, light collimation and light focusing of the converted light emitted from the color conversion optical wafer.

25. The method of manufacturing a display of claim 21, further comprising:
fabricating black matrices on the color conversion optical wafer for separating distinct color conversion sections of the color conversion optical wafer.

26. The method of manufacturing a display of claim 21, further comprising:
fabricating the side surfaces of the LEDs to include a sloped region coated by the light reflecting sidewalls, such that the sloped region comes to a point.
